(19) United States
(12) Patent Application Publication
(10) Pub. No.: US 2024/0164028 A1
(43) Pub. Date: May 16, 2024

(54) PRINTED CIRCUIT BOARD AND MANUFACTURING METHOD FOR THE SAME

(71) Applicant: SAMSUNG ELECTRO-MECHANICS CO., LTD., Suwon-si (KR)

(72) Inventors: Seon Ha Kang, Suwon-si (KR); Seung Eun Lee, Suwon-si (KR); Yong Hoon Kim, Suwon-si (KR)

(73) Assignee: SAMSUNG ELECTRO-MECHANICS CO., LTD., Suwon-si (KR)

(21) Appl. No.: 18/218,753

(22) Filed: Jul. 6, 2023

(30) Foreign Application Priority Data
Nov. 16, 2022 (KR) 10-2022-0153873
Jan. 20, 2023 (KR) 10-2023-0008891

(51) Int. Cl. H05K 3/46; H05K 1/03; H05K 1/11; H05K 3/00; H05K 3/12

(52) U.S. Cl. CPC H05K 3/4688; H05K 1/03; H05K 1/115; H05K 3/0017; H05K 3/1258; H05K 2201/09045; H05K 2203/0574

(57) ABSTRACT

A printed circuit board including a first insulating layer; a plurality of first circuit patterns respectively disposed on the first insulating layer; and a plurality of second circuit patterns respectively disposed on the first insulating layer and respectively having a thickness, thinner than a thickness of each of the plurality of first circuit patterns. At least one of the plurality of first circuit patterns and at least one of the plurality of second circuit patterns are alternately and repeatedly arranged, and a method for manufacturing the printed circuit board, are provided.

### CROSS-REFERENCE TO RELATED APPLICATION(S)

This application claims benefit of priority to Korean Patent Application No. 10-2022-0153873 filed on Nov. 16, 2022 and Korean Patent Application No. 10-2023-0008891 filed on Jan. 20, 2023 in the Korean Intellectual Property Office, the disclosures of which are incorporated herein by reference in their entireties.

### TECHNICAL FIELD

The present disclosure relates to a printed circuit board, for example, a printed circuit board including a microcircuit, and a manufacturing method thereof.

Recently, in the electronic components industry, highly integrated printed circuit boards to cope with 5G high-speed communication and artificial intelligence have been required. A microcircuit is a key technology for manufacturing highly integrated printed circuit boards, and, for example, research and development is actively underway to secure technologies capable of implementing microcircuits with a line/space of approximately several microns. However, in conventional circuit formation methods, such as a semi-additive process (SAP), a modified semi-additive process (MSAP), or the like, there are limitations in implementing microcircuits having the above-described range of line/space due to a limit to resolution of exposure equipment and margins in the seed etching process.

### SUMMARY

One of the various objects of the present disclosure is to provide a printed circuit board capable of forming a microcircuit and a manufacturing method thereof.

One of various solutions proposed by the present disclosure is to prepare a microcircuit by forming a plurality of first metal patterns in a first plating process, forming a metal layer thereon, forming a plurality of second metal patterns thereon in a second plating process, and then selectively etching the metal layer.

For example, a method for manufacturing a printed circuit board according to an example includes forming a plurality of first metal patterns on a substrate; forming a metal layer covering the plurality of first metal patterns on the substrate, and including a metal, different from that of the plurality of first metal patterns; forming a plurality of second metal patterns on the metal layer, filling at least a portion of a space between external side surfaces of the metal layer, and including a metal, different from the metal of the metal layer, respectively; etching a portion of the metal layer to expose at least a portion of each of the plurality of first metal patterns from the metal layer; forming a first insulating layer on the plurality of first metal patterns and the plurality of second metal patterns; removing the substrate; and etching a remaining portion of the metal layer.

In addition, a printed circuit board according to an example includes a first insulating layer; a plurality of first circuit patterns respectively disposed on the first insulating layer; and a plurality of second circuit patterns respectively disposed on the first insulating layer and respectively having a thickness, thinner than a thickness of each of the plurality of first circuit patterns. At least one of the plurality of first circuit patterns and at least one of the plurality of second circuit patterns are alternately and repeatedly arranged.

Alternatively, a printed circuit board according to an example includes a first insulating layer; a first wiring layer disposed above the first insulating layer, and including a first circuit pattern and a second circuit pattern, having different thicknesses; and a second wiring layer disposed below the first insulating layer, and including a third circuit pattern having a line width, respectively wider than a line width of the first circuit pattern and a line width of the second circuit pattern. Alternatively, a printed circuit board according to an example includes: an insulating layer; a first wiring layer protruding from an upper surface of the insulating layer, and including circuit patterns having different thicknesses; a second wiring layer disposed below the insulating layer; and a connection via passing through the insulating layer and connecting the first wiring layer and the second wiring layer to each other. The connection via is tapered to substantially decrease a width in a direction from a surface contacting the second wiring layer to a surface contacting the first wiring layer.

Alternatively, a printed circuit board according to an example includes: an insulating layer; and a wiring layer protruding from an upper surface of the insulating layer, and including first circuit patterns and second circuit patterns periodically disposed. Each of the first circuit patterns has one or more grooves on a side in contact with the insulating layer, and each of the second circuit patterns has one or more protrusions on a side in contact with the insulating layer.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram schematically illustrating an example of an electronic device system.

FIG. 2 is a perspective view schematically illustrating an example of an electronic device.

FIG. 3 is a schematic cross-sectional view of an example of a printed circuit board.

FIGS. 4 to 6 are cross-sectional views schematically illustrating modified examples of the printed circuit board of FIG. 3.

FIGS. 7A to 7K are process cross-sectional views schematically illustrating an example of manufacturing the printed circuit board of FIG. 3.

FIGS. 8A to 8D are process cross-sectional views schematically illustrating shapes of a plurality of first metal patterns, a plurality of second metal patterns, and a plurality of metal layers, and etching degrees of some of the metal layers, for manufacturing the printed circuit boards of FIGS. 3 to 6, respectively.

FIGS. 9 to 12 are cross-sectional views schematically illustrating cases in which the printed circuit boards of FIGS. 3 to 6 are applied to a multilayer printed circuit board.

FIG. 13 is a cross-sectional view schematically illustrating another example of a printed circuit board.

FIGS. 14 to 16 are cross-sectional views schematically illustrating modified examples of the printed circuit board of FIG. 13.

FIGS. 17A to 17L are process cross-sectional views schematically illustrating an example of manufacturing the printed circuit board of FIG. 13.

FIGS. 18A to 18D are process cross-sectional views schematically illustrating shapes of a plurality of first metal patterns, a plurality of second metal patterns, and a plurality of metal layers, and etching degrees of some of the metal layers, for manufacturing the printed circuit boards of FIGS. 13 to 16, respectively.

FIGS. 19 to 22 are cross-sectional views schematically illustrating cases in which the printed circuit boards of FIGS. 13 to 16 are applied to a multilayer printed circuit board.

### DETAILED DESCRIPTION

Hereinafter, the present disclosure will be described with reference to the accompanying drawings. Shapes and sizes of elements in the drawings may be exaggerated or reduced for clarity.

Electronic Device

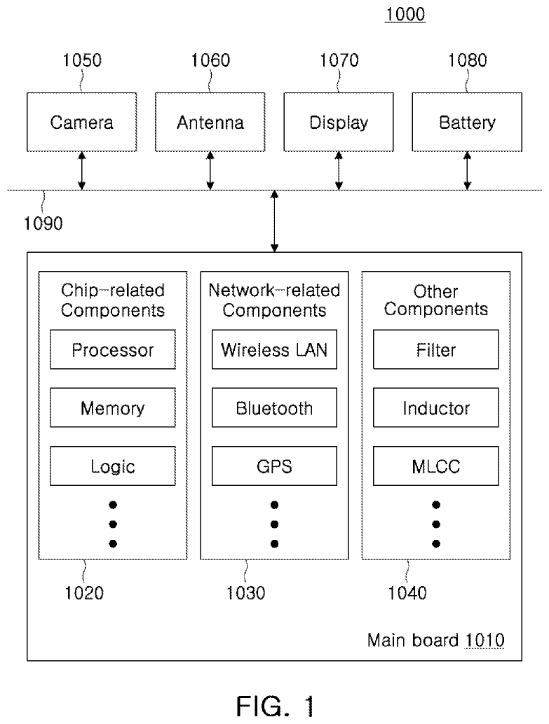

FIG. 1 is a block diagram schematically illustrating an example of an electronic device system.

Referring to the drawing, an electronic device 1000 may accommodate a main board 1010 therein. The main board 1010 may include chip related components 1020, network related components 1030, other components 1040, and the like, physically and/or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter, an application-specific integrated circuit (ASIC), or the like. However, the chip related components 1020 are not limited thereto, but may also include other types of chip related components.

In addition, the chip related components 1020 may be combined with each other. The chip related component 1020 may be in the form of a package including the above-described chip or an electronic component.

The network related components 1030 may include components compatible with or communicating using various protocols such as wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include components compatible with or communicating using a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 and/or the network related components 1030 described above.

Depending on a type of the electronic device 1000, the electronic device 1000 may include other components that may or may not be physically and/or electrically connected to the main board 1010. These other components may include, for example, a camera module 1050, an antenna module 1060, a display device 1070, a battery 1080, or the like. However, these other components are not limited thereto, and may also include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. These other components may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

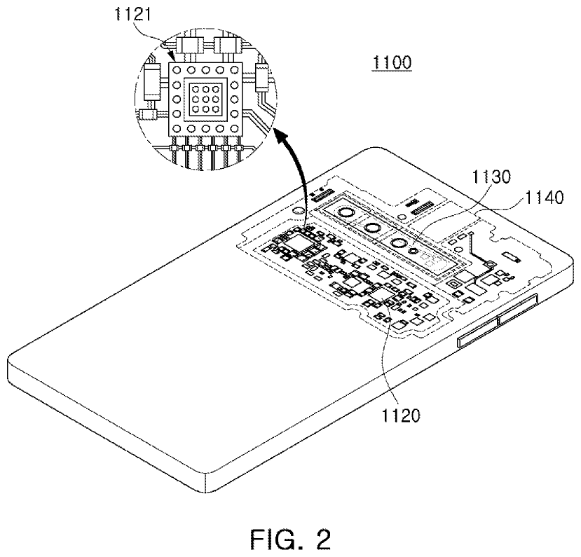

FIG. 2 is a perspective view schematically illustrating an example of an electronic device.

Referring to the drawing, an electronic device may be, for example, a smartphone 1100. A motherboard 1110 may be accommodated inside the smartphone 1100, and various components 1120 may be physically and/or electrically connected to the motherboard 1110. In addition, other components, such as a camera module 1130 and/or a speaker 1140, that may or may not be physically and/or electrically connected to the motherboard 1110, may be accommodated therein. A portion of the components 1120 may be the aforementioned chip-related components, for example, a component package 1121, but are not limited thereto. The component package 1121 may be provided as a printed circuit board on which electronic components including active components and/or passive components are surface mounted. Alternatively, the component package 1121 may be provided as a printed circuit board in which active components and/or passive components are embedded. The electronic device is not necessarily limited to the smartphone 1100, but may be other electronic devices as described above.

Printed Circuit Board

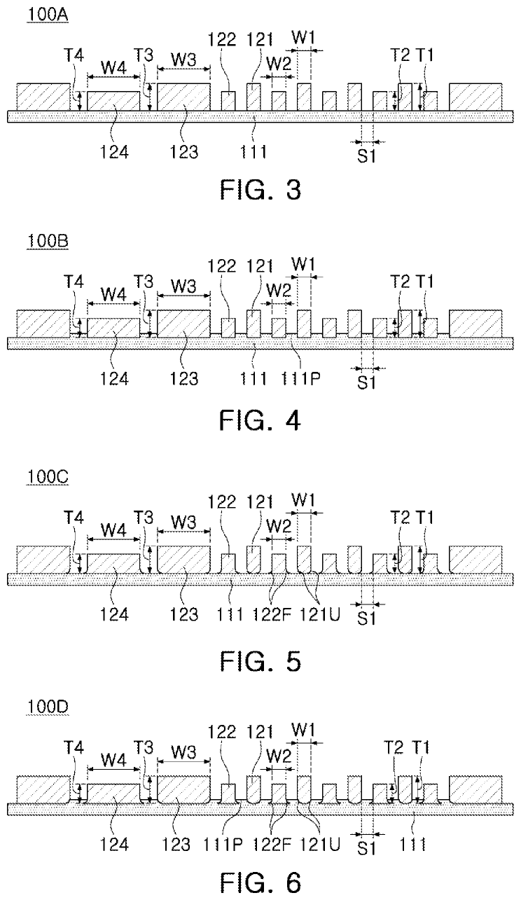

FIG. 3 is a schematic cross-sectional view of an example of a printed circuit board.

Referring to the drawings, a printed circuit board 100A according to an example may include a first insulating layer 111, a plurality of first circuit patterns 121 respectively disposed on the first insulating layer 111, and a plurality of second circuit patterns 122 respectively disposed on the first insulating layer 111. A thickness T1 of each of the plurality of first circuit patterns 121 may be thicker than a thickness T2 of each of the plurality of second circuit patterns 122. One first circuit pattern among the plurality of first circuit patterns 121 and one second circuit pattern among the plurality of second circuit patterns 122 may be alternately and repeatedly arranged. The alternating and repeating arrangement may be performed in an alternating arrangement manner at least twice, and, for example, a second circuit pattern 122, a first circuit pattern 121, a second circuit pattern 122, a first circuit pattern 121, a second circuit pattern 122, and the like may be disposed on the first insulating layer 111 in order. The number of alternating and repeating arrangements of the plurality of first and second circuit patterns 121 and 122 is not particularly limited, and may be variously changed according to a design. In this repeated arrangement, a line width W1 of the one first circuit pattern 121, a line width W2 of the one second circuit pattern 122, and an interval S1 between the one first circuit pattern 121 and the one second circuit pattern 122 may be substantially equal to each other.

The plurality of first and second circuit patterns 121 and 122 may be microcircuit patterns. For example, line widths W1 and W2 of each of the plurality of first and second circuit patterns 121 and 122 may be 10 μm or less, 5 μm or less, or 2 μm or less. Also, the interval S1 between the plurality of first and second circuit patterns 121 and 122 may be 10 μm or less, 5 μm or less, or 2 μm or less, respectively. For example, the plurality of first and second circuit patterns 121 and 122 may be a microcircuit pattern having an L (Line)/S (Space) of 10 μm/10 μm or less, 5 μm/5 μm or less, or 2 μm/2 μm or less.

A printed circuit board 100A according to an example of such a structure may be formed by a new process to be described later, and in this case, unlike conventional SAP, MSAP, or the like, it is possible to overcome a limitation of resolution of exposure equipment, and a separate seed etching process may not be performed, and as a result, a microcircuit pattern having an L/S of 10 μm/10 μm or less, or 5 μm/5 μm or less, or 2 μm/2 μm or less may be easily formed.

A printed circuit board 100A according to an example may further include at least one third circuit pattern 123 respectively disposed on the first insulating layer 111 and having a width or a line width W3, wider than the line widths W1 and W2 of each of the plurality of first and second circuit patterns 121 and 122. The at least one third circuit pattern 123 may include a general circuit pattern, not a microcircuit pattern, for example, a general circuit pattern having a line width and an interval therebetween exceeding 10 μm, and/or a pad pattern, for example, a pad pattern having a width exceeding 10 μm.

A printed circuit board 100A according to an example may further include at least one fourth circuit pattern 124 respectively disposed on the first insulating layer 111 and having a width or a line width W4, wider than the line widths W1 and W2 of each of the plurality of first and second circuit patterns 121 and 122. A thickness T4 of the at least one fourth circuit pattern 124 may be thinner than a thickness T3 of the at least one third circuit pattern 123. The at least one fourth circuit pattern 124 may include a general circuit pattern, not a microcircuit pattern, for example, a general circuit pattern having a line width and an interval therebetween exceeding 10 μm, and/or a plain pattern, for example, a plain pattern having a width exceeding 10 μm.

Hereinafter, components of a printed circuit board 100A according to an example will be described in more detail with reference to the drawings.

The first insulating layer 111 may include an insulating material. The insulating material may include a thermosetting resin such as an epoxy resin, a thermoplastic resin such as polyimide, or a material including an inorganic filler, an organic filler, and/or glass fiber (glass cloth, glass fabric) together with a resin. For example, the insulating material may be a non-photosensitive insulating material such as Ajinomoto Build-up Film (ABF), a prepreg (PPG), or the like, but is not limited thereto, and other polymer materials may be used. In addition, the insulating material may be a photosensitive insulating material such as a photoimageable dielectric (PID) or the like.

Each of the plurality of first and second circuit patterns 121 and 122 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the plurality of first and second circuit patterns 121 and 122 may perform various functions according to a design. For example, a signal pattern may be included. Each of the plurality of first and second circuit patterns 121 and 122 may not include a separate seed metal layer. For example, each of the plurality of first and second circuit patterns 121 and 122 may include an electrolytic plating layer (or electrolytic copper), and may not include an electroless plating layer (or chemical copper) or a sputter layer.

Each of the at least one third and fourth circuit patterns 123 and 124 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the at least one third and fourth circuit patterns 123 and 124 may perform various functions according to a design. For example, a signal pattern, a power pattern, or a ground pattern may be included. Each of these patterns may include a line pattern, a pad pattern, a plain pattern, or the like. Each of the at least one third and fourth circuit patterns 123 and 124 may not include a separate seed metal layer. For example, each of the at least one third and fourth circuit patterns 123 and 124 may include an electrolytic plating layer (or electrolytic copper), and may not include an electroless plating layer (or chemical copper) or a sputter layer.

FIGS. 4 to 6 are cross-sectional views schematically illustrating modified examples of the printed circuit board of FIG. 3.

Referring to FIG. 4, in a printed circuit board 100B according to a modified example, a portion 111P of a first insulating layer 111 may protrude and be disposed between a plurality of first circuit patterns 121 and between a plurality of second circuit patterns 122, as compared to a printed circuit board 100A according to an example. For example, in the above-described repeated arrangement, in cross-sectional view, the portion 111P of the first insulating layer 111 may protrude and be disposed between at least one of one side surface or the other side surface of each of the first circuit patterns 121 and one side surface or the other side surface of each of the second circuit patterns 122. In this case, connection reliability between the first insulating layer 111 and the plurality of first and second circuit patterns 121 and 122 may be further improved. The portion 111P of the first insulating layer 111 may also protrude and be disposed between at least one of each of the plurality of first circuit patterns 121 or each of the plurality of second circuit patterns 122 and at least one of the at least one third circuit patterns 123 or the at least one fourth circuit patterns 124. In addition, the portion 111P may protrude and be disposed between the at least one third and fourth circuit patterns 123 and 124. In this case, connection reliability between the first insulating layer 111 and the at least one third and fourth circuit patterns 123 and 124 may be further improved.

Referring to FIG. 5, in a printed circuit board 100C according to another modified example, an undercut may be formed on at least a portion of each lower side of a plurality of first circuit patterns 121, and a foot may be formed on at least a portion of each lower side of a plurality of second circuit patterns 122, as compared to a printed circuit board 100A according to an example. For example, in the above-described repeated arrangement, in cross-sectional view, one first circuit pattern 121 may have grooves 121U on lower sides of both side surfaces, and one second circuit pattern 122 may have protrusions 122F on lower sides of both side surfaces. In this case, connection reliability between a first insulating layer 111 and the plurality of first and second circuit patterns 121 and 122 may be further improved. The undercut may also be formed on at least a portion of a lower side of at least one third circuit pattern 123, and the foot may also be formed on at least a portion of a lower side of at least one fourth circuit pattern 124. In this case, connection reliability between the first insulating layer 111 and the at least one third and fourth circuit patterns 123 and 124 may be further improved. The line widths W1 and W2 of each of the plurality of first and second circuit patterns 121 and 122 and the interval S1 between the plurality of first and second circuit patterns 121 and 122 may be defined based on side surfaces of the plurality of first and second circuit patterns 121 and 122, without considering the structure of the undercut or the foot. Referring to FIG. 6, in a printed circuit board 100D according to another modified example, a portion 111P of a first insulating layer 111 may protrude and be disposed between a plurality of first circuit patterns 121 and between a plurality of second circuit patterns 122, as compared to a printed circuit board 100A according to an example. In addition, an undercut may be formed on at least a portion of a lower side of each of the plurality of first circuit patterns 121, and a foot may be formed on at least a portion of a lower side of each of the plurality of second circuit patterns 122. A specific structure and effect thereof may be as described above. The portion 111P of the first insulating layer 111 may also protrude and be disposed between at least one of each of the plurality of first circuit patterns 121 or each of the plurality of second circuit patterns 122 and at least one of at least one third circuit pattern 123 or at least one fourth circuit pattern 124, and may also protrude and be disposed between the at least one third and fourth circuit patterns 123 and 124. In addition, the undercut may also be formed on at least a portion of a lower side of the at least one third circuit pattern 123, and the foot may also be formed on at least a portion of a lower side of the at least one fourth circuit pattern 124. A specific structure and effect thereof may be as described above. The line widths W1 and W2 of each of the plurality of first and second circuit patterns 121 and 122 and the interval S1 between the plurality of first and second circuit patterns 121 and 122 may be defined based on side surfaces of the plurality of first and second circuit patterns 121 and 122, without considering the structure of the undercut or the foot. Others may be substantially the same as those described in a printed circuit board 100A according to the above-described example, overlapping description thereof will be omitted.

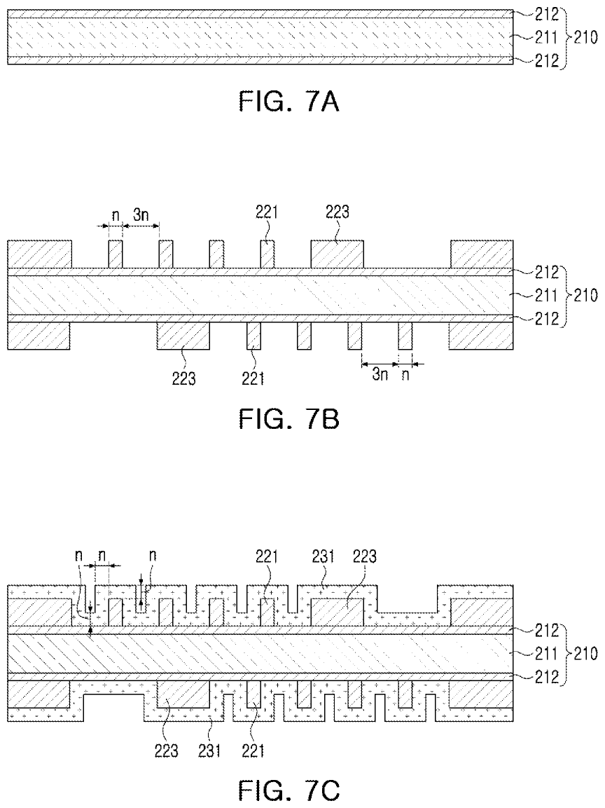

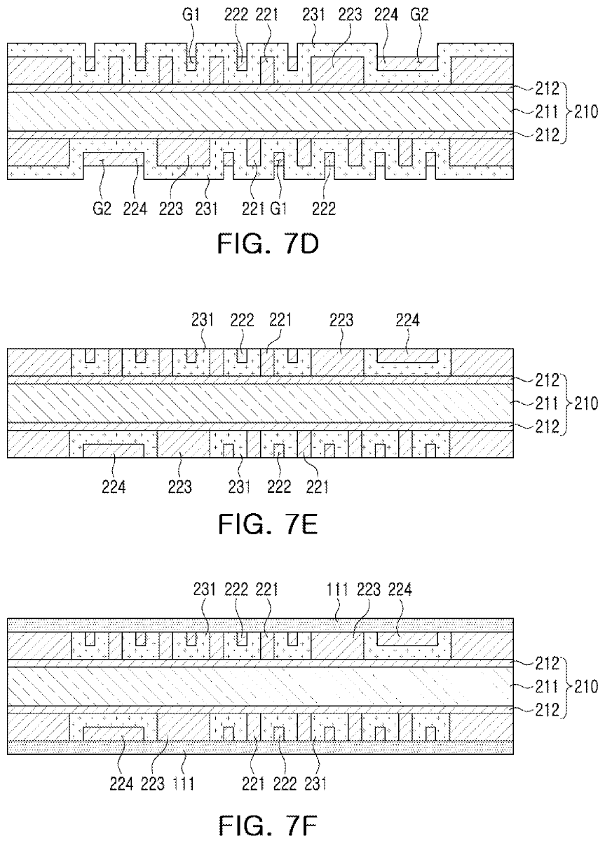

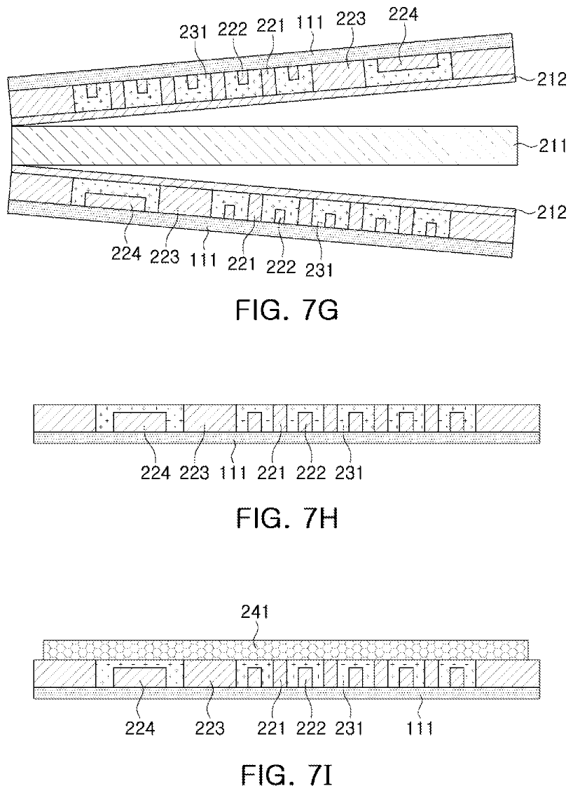

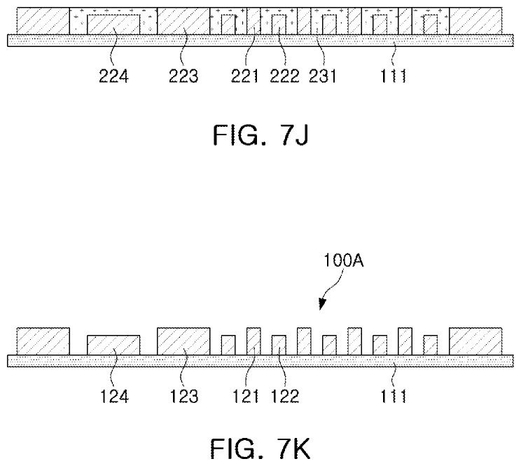

FIGS. 7A to 7K are process cross-sectional views schematically illustrating an example of manufacturing the printed circuit board of FIG. 3.

Referring to the drawings, a method of manufacturing a printed circuit board 100A according to an example may include forming a plurality of first metal patterns 221 on a substrate 210; forming a metal layer 231 covering the plurality of first metal patterns 221 on the substrate 210, and including a metal, different from that of the plurality of first metal patterns 221; forming a plurality of second metal patterns 222 on the metal layer 231, filling at least a portion of a space G1 between external side surfaces of the metal layer 231, and including a metal, different from the metal of the metal layer 231, respectively; etching a portion of the metal layer 231 to expose at least a portion of each of the plurality of first metal patterns 221 from the metal layer 231; forming a first insulating layer 111 on the plurality of first metal patterns 221 and the plurality of second metal patterns 222; removing the substrate 210; and etching a remaining portion of the metal layer 231. For example, the metal layer 231 may have different etching rates with respect to an etchant for etching the plurality of first and second metal patterns 221 and 222 and the metal layer 231. For example, the plurality of first and second metal patterns 221 and 222 may include copper (Cu), and the metal layer 231 may include nickel (Ni), but are not limited thereto.

In the forming a plurality of first metal patterns 221, if a width of each of the plurality of first metal patterns 221 is n, an interval between the plurality of first metal patterns 221 may substantially satisfy 3n, respectively. Also, in the forming a metal layer 231, a thickness or a width of the metal layer 231 may substantially satisfy n. Therefore, a microcircuit having an L/S of n/n may be finally formed. In this manner, even if the initial interval of the metal pattern is 3n, a line width and an interval of the microcircuit may be finally formed as n, respectively.

As described above, a printed circuit board 100A according to an example formed by this manufacturing method may easily form an interval between first metal patterns. In this case, unlike conventional SAP, MSAP, or the like, it is possible to overcome a limitation of resolution of exposure equipment, and a separate seed etching process may not be performed. As a result, a microcircuit pattern having an L/S of 10 μm/10 μm or less, 5 μm/5 μm or less, or 2 μm/2 μm or less may be easily formed.

A method of manufacturing a printed circuit board 100A according to an example may further include forming at least one third metal pattern 223 having a width or a line width, respectively wider than a width or a line width of each of the plurality of first metal patterns 221, on the substrate 210. The at least one third metal pattern 223 may be formed together, when forming the plurality of first metal patterns 221. The at least one third metal pattern 223 may include metal, different from metal of the metal layer 231. For example, the at least one third metal pattern 223 may include copper (Cu), but is not limited thereto.

A method of manufacturing a printed circuit board 100A according to an example may further include forming at least one fourth circuit pattern 224 filling at least a portion of a different space G2 between external side surfaces of the metal layer 231, respectively, and having a width or a line width, respectively wider than a width or a line width of each of the plurality of second metal patterns 222, on the metal layer 231. The at least one fourth metal pattern 224 may be formed together, when forming the plurality of second metal patterns 222. The at least one fourth metal pattern 224 may include metal, different from the metal of the metal layer 231. For example, the at least one fourth metal pattern 224 may include copper (Cu), but is not limited thereto.

A method of manufacturing a printed circuit board 100A according to an example may further include, after the removing the substrate 210, forming a dry film 241 exposing a portion of at least one of the plurality of first metal patterns 221, the plurality of second metal patterns 222, the at least one third metal pattern 223, or the at least one fourth metal pattern 224, on the plurality of first metal patterns 221, the plurality of second metal patterns 222, the at least one third metal pattern 223, and the at least one fourth metal pattern 224; and etching an exposed portion of at least one of the plurality of first metal patterns 221, the plurality of second metal patterns 222, the at least one third metal pattern 223, or the at least one fourth metal pattern 224. Through this, a portion connected to each other, an unnecessary portion, or the like, among the plurality of first metal patterns 221, the plurality of second metal patterns 222, the at least one third metal pattern 223, and/or the at least one fourth metal pattern 224, may be removed.

Hereinafter, a method of manufacturing a printed circuit board 100A according to an example will be described in more detail with reference to the drawings.

Referring to FIG. 7A, a substrate 210 may be prepared. The substrate 210 may be a copper clad laminate (CCL), but is not limited thereto, and various types of detachable carrier substrates may be used. The substrate 210 may include a detachable core 211 and a detachable metal layer 212. The detachable metal layer 212 may be disposed on one side surface or both side surfaces of the detachable core 211. The detachable core 211 may include an insulating material, for example, an epoxy resin impregnated with a glass fiber, and the detachable metal layer 212 may include metal, for example, copper (Cu). As necessary, a releasable layer may be further disposed between the detachable core 211 and the detachable metal layer 212.

Referring to FIG. 7B, a plurality of first metal patterns 221 may be formed on the substrate 210. In this case, at least one third metal pattern 223 having a width, wider than a width of each of the plurality of first metal patterns 221, may be further formed. The plurality of first metal patterns 221 and the at least one third metal pattern 223 may form a dry film including a photosensitive insulating material on the substrate 210, a pattern opening may be formed in the dry film by a photolithography process, for example, an exposure and development process, and the detachable metal layer 212 exposed through the pattern opening as a seed metal layer may be formed by filling at least a portion of the pattern opening by a plating process, for example, electrolytic plating (as electrolytic copper). The at least one third metal pattern 223 may include a metal, identical to a metal of the plurality of first metal patterns 221, for example, copper (Cu). If the width of each of the plurality of first metal patterns 221 is n, an interval between the plurality of first metal patterns 221 may substantially satisfy 3n.

Referring to FIG. 7C, a metal layer 231 covering the plurality of first metal patterns 221 and the at least one third metal pattern 223 may be formed on the plurality of first metal patterns 221 and the at least one third metal pattern 223. The metal layer 231 may be formed by a plating process, for example, electrolytic plating (as electrolytic copper). The metal layer 231 may include a metal, different from the plurality of first metal patterns 221 and the at least one third metal pattern 223, for example, nickel (Ni). If the width of each of the plurality of first metal patterns 221 is n, a thickness or a width of the metal layer 231 may substantially satisfy n.

Referring to FIG. 7D, a plurality of second metal patterns 222 filling at least a portion of a space G1 between external side surfaces of the metal layer 231 may be formed on the metal layer 231. In this case, at least one fourth metal pattern 224 filling at least a portion of a different space G2 between external side surfaces of the metal layer 231 may be further formed on the metal layer 231. The plurality of second metal patterns 222 and the at least one fourth metal pattern 224 may be formed by filling at least a portion of the space G1 and at least a portion of the spaces G2 by a plating process, for example, electrolytic plating (as electrolytic copper). The at least one fourth metal pattern 224 may include the same metal as the plurality of second metal patterns 222, for example, copper (Cu). If the width of each of the plurality of first metal patterns 221 is n, a width of each of the plurality of second metal patterns 222 may substantially satisfy n.

Referring to FIG. 7E, at least a portion of each of the plurality of first metal patterns 221 and at least a portion of each of the at least one third metal pattern 223 may be exposed from the metal layer 231 by etching a portion of the metal layer 231, or alternatively, by a polishing process such as chemical mechanical polishing (CMP). The metal layer 231 may include a metal, different from the metal of the plurality of first metal patterns 221 and the metal of the at least one third metal pattern 223, for example, nickel (Ni), and may thus be selectively etched with an etching solution for nickel (Ni). The etching solution for nickel (Ni) may use an etching ratio of at least 8:2 or more between nickel (Ni) and copper (Cu).

Referring to FIG. 7F, a first insulating layer 111 may be formed on the plurality of first and second metal patterns 221 and 222 and the at least one third and fourth metal patterns 223 and 224. The first insulating layer 111 may be formed by stacking and curing an uncured film, but is not limited thereto.

Referring to FIGS. 7G and 7H, the substrate 210 may be removed. The detachable core 211 may be separated and removed from the detachable metal layer 212. The detachable metal layer 212 remaining after the separation and removal of the detachable core 211 may be etched and removed.

Referring to FIG. 7I, a dry film 241 exposing a portion of at least one of the plurality of first metal patterns 221, the plurality of second metal patterns 222, the at least one third metal pattern 223, or the at least one fourth metal pattern 224, may be formed on the plurality of first and second metal patterns 221 and 222 and the at least one third and fourth metal patterns 223 and 224. The dry film 241 may include a negative-type photosensitive insulating material or a positive-type photosensitive insulating material. A portion of the dry film 241 may be removed a photolithography process, for example, an exposure and development process, through which a portion of at least one of the plurality of first metal patterns 221, the plurality of second metal patterns 222, the at least one third metal pattern 223, or the at least one fourth metal pattern 224 may be selectively exposed.

Referring to FIG. 7J, an exposed portion of at least one of the plurality of first and second metal patterns 221 and 222 or the at least one third and fourth metal patterns 223 and 224 may be etched. Through this, a portion connected to each other, an unnecessary portion, or the like, among the plurality of first metal patterns 221, the plurality of second metal patterns 222, the at least one third metal pattern 223, and/or the at least one fourth metal pattern 224, may be selectively removed.

Referring to FIG. 7K, a remaining portion of the metal layer 231 may be etched. A plurality of first circuit patterns 121, a plurality of second circuit patterns 122, at least one third circuit pattern 123, and at least one fourth circuit pattern 124 may be formed from the plurality of first metal patterns 221, the plurality of second metal patterns 222, the at least one third metal pattern 223, and the at least one fourth metal pattern 224 by etching the metal layer 231.

Since the printed circuit board 100A according to the above-described example may be formed by a series of processes, and others may be substantially the same as those described in the printed circuit board 100A according to the above-described example, overlapping description thereof will be omitted.

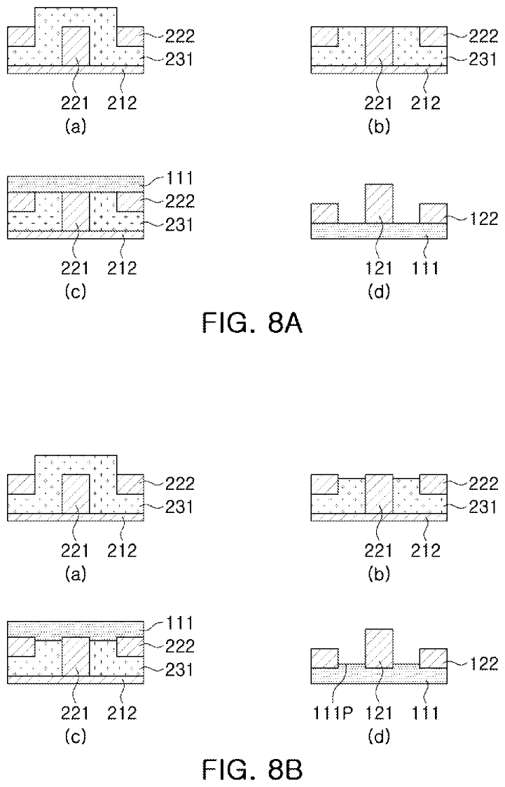

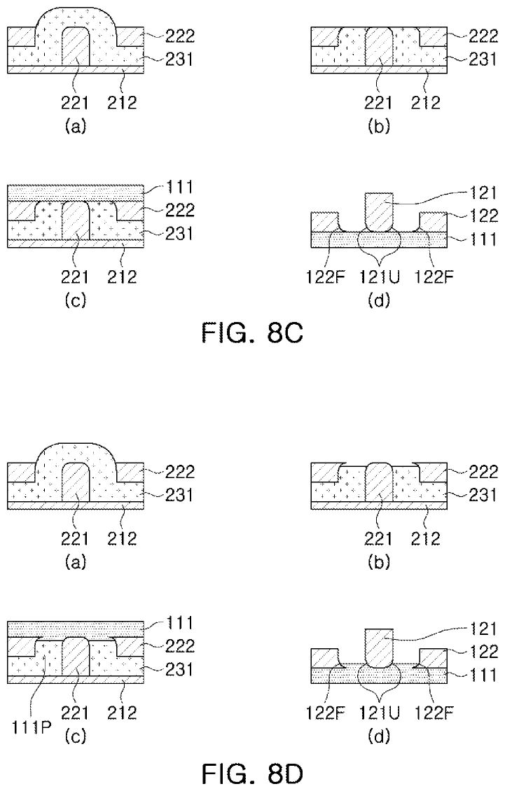

FIGS. 8A to 8D are process cross-sectional views schematically illustrating shapes of a plurality of first metal patterns, a plurality of second metal patterns, and a plurality of metal layers, and etching degrees of some of the metal layers, for manufacturing the printed circuit boards of FIGS. 3 to 6, respectively.

Referring to FIG. 8A, as in (a), at least a portion of an edge of each top surface of a plurality of first metal patterns 221 may be formed substantially vertically, and, thus, at least a portion of an edge of a top surface of a metal layer 231, and at least a portion of an edge of each top surface of a plurality of second metal patterns 222 may be formed substantially vertically. In this case, at least a portion of an edge of a top surface of at least one third metal pattern 223 and at least a portion of an edge of a top surface of at least one fourth metal pattern 224 may be formed substantially vertically. In addition, as in (b), when the metal layer 231 is selectively removed, the top surface of the metal layer 231 may be etched to be substantially coplanar with the top surface of each of the plurality of first and second metal patterns 221 and 222. In this case, the top surface of the metal layer 231 may also be etched to be substantially coplanar with the top surface of each of the at least one third and fourth metal patterns 223 and 224. Therefore, as in (c), a first insulating layer 111 may be formed on the substantially coplanar surface. Also, as in (d), an undercut or a foot may not be formed on a bottom side of each of the plurality of first and second circuit patterns 121 and 122. In this case, the undercut or the foot may not be formed on a bottom side of the at least one third and fourth circuit patterns 123 and 124. In addition, a top surface of the first insulating layer 111 may be substantially flat without a step difference. For example, a structure of a printed circuit board 100A according to an example may be formed.

Referring to FIG. 8B, unlike in FIG. 8A, in (b), when a metal layer 231 is selectively removed, the metal layer 231 may be excessively etched, and a top surface of the metal layer 231 may be etched to have a step difference with each top surface of a plurality of first metal patterns 221 and each top surface of a plurality of second metal patterns 222. In this case, the metal layer 231 may also be etched to have a step difference with a top surface of at least one third metal pattern 223 and a top surface of at least one fourth metal pattern 224. Therefore, in (c), the first insulating layer 111 may extend to reach the excessively etched region. Also, in (d), a portion 111P of the first insulating layer 111 may protrude between the plurality of first and second circuit patterns 121 and 122. In this case, the portion 111P may also protrude between the at least one third and fourth circuit patterns 123 and 124, or the like. For example, a structure of a printed circuit board 100B according to a modified example may be formed.

Referring to FIG. 8C, unlike in FIG. 8A, in (a), at least a portion of an edge of each top surface of a plurality of first metal patterns 221 may be formed to be rounded. Therefore, at least a portion of an edge of a top surface of a metal layer 231 may be formed to be rounded, and at least a portion of an edge of each top surface of a plurality of second metal patterns 222 may be formed to be pointed. In this case, at least a portion of an edge of a top surface of at least one third metal pattern 223 and at least a portion of an edge of a top surface of at least one fourth metal pattern 224 may also be formed to be rounded or pointed. Therefore, in (d), an undercut or a foot, for example, a groove 121U and a protrusion 122F may be formed on at least a portion of a bottom side of each of the plurality of first and second circuit patterns 121 and 122. In this case, the undercut or the foot may also be formed on at least a portion of a bottom side of each of the at least one third and fourth circuit patterns 123 and 124. For example, a structure of a printed circuit board 100C according to another modified example may be formed.

Referring to FIG. 8D, unlike in FIG. 8A, in (a), at least a portion of an edge of each top surface of a plurality of first metal patterns 221 may be formed to be rounded. Therefore, at least a portion of an edge of a top surface of a metal layer 231 may be formed to be rounded, and at least a portion of an edge of each top surface of a plurality of second metal patterns 222 may be formed to be pointed. In this case, at least a portion of an edge of a top surface of at least one third metal pattern 223 and at least a portion of an edge of a top surface of at least one fourth metal pattern 224 may also be formed to be rounded or pointed. In addition, when the metal layer 231 is selectively removed in (b), the metal layer 231 may be excessively etched, such that the top surface of the metal layer 231 has a step difference with the top surface of each of the plurality of first and second metal patterns 221 and 222. In this case, the metal layer 231 may also be etched to have a step difference with the top surface of each of the at least one third and fourth metal patterns 223 and 224. Therefore, in (c), the first insulating layer 111 may extend to reach the excessively etched region. Also, in (d), a portion 111P of the first insulating layer 111 may protrude between the plurality of first and second circuit patterns 121 and 122. In this case, the portion 111P may also protrude between the at least one third and fourth circuit patterns 123 and 124, or the like. In addition, an undercut or a foot, for example, a groove 121U and a protrusion 122F may be formed on at least a portion of a bottom side of each of the plurality of first and second circuit patterns 121 and 122. In this case, the undercut or the foot may also be formed on at least a portion of a bottom side of each of the at least one third and fourth circuit patterns 123 and 124. For example, a structure of a printed circuit board 100D according to another modified example may be formed.

Since others may be substantially the same as those described in the above-described printed circuit boards 100A, 100B, 100C, and 100D and the manufacturing method of the above-described printed circuit board 100A, overlapping description thereof will be omitted.

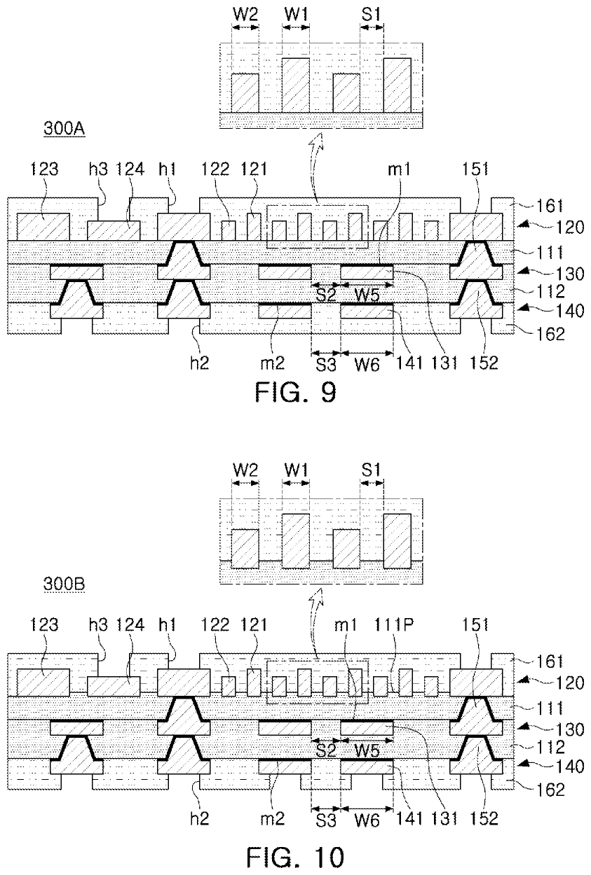

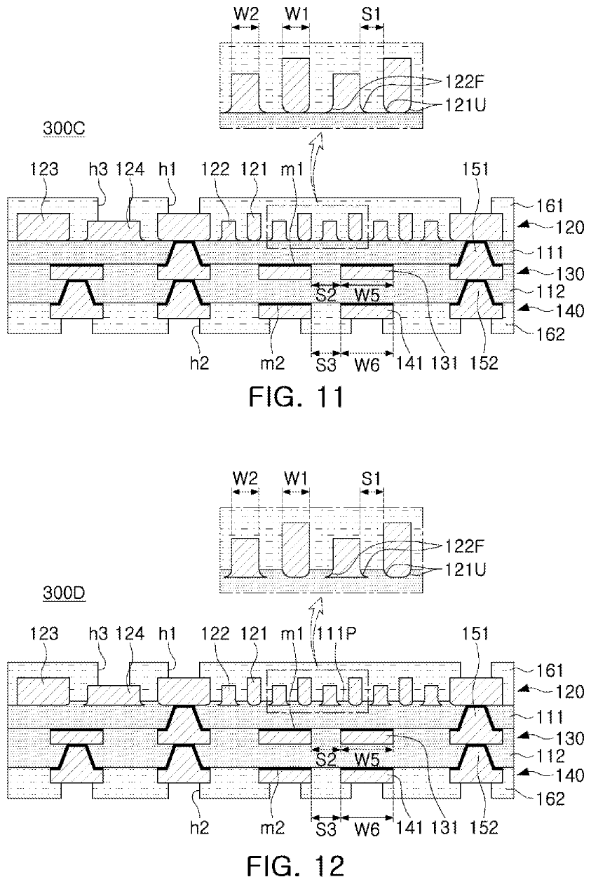

FIGS. 9 to 12 are cross-sectional views schematically illustrating cases in which the printed circuit boards of FIGS. 3 to 6 are applied to a multilayer printed circuit board.

Referring to the drawings, multilayer printed circuit boards 300A, 300B, 300C, and 300D may further include a first wiring layer 120 disposed on an upper surface of a first insulating layer 111 and including a plurality of first circuit patterns 121, a plurality of second circuit patterns 122, at least one third circuit pattern 123, and at least one fourth circuit pattern 124, a second wiring layer 130 disposed on a lower surface of the first insulating layer 111 and including a plurality of fifth circuit patterns 131, a first connection via 151 passing through the first insulating layer 111 and connected to at least a portion of the second wiring layer 130, a second insulating layer 112 disposed on the lower surface of the first insulating layer 111 and covering at least a portion of the second wiring layer 130, a third wiring layer 140 disposed on a lower surface of the second insulating layer 112 and including a plurality of sixth circuit patterns 141, and a second connection via 152 passing through the second insulating layer 112 and connected to at least a portion of the third wiring layer 140, as compared to the aforementioned printed circuit boards 100A, 100B, 100C, and 100D. As necessary, a first resist layer 161 disposed on the upper surface of the first insulating layer 111 and covering at least a portion of the first wiring layer 120, and a second resist layer 162 disposed on the lower surface of the second insulating layer 112 and covering at least a portion of the third wiring layer 140, may be further included.

A width or a line width W5 of each of the plurality of fifth circuit patterns 131 and a width or a line width W6 of each of the plurality of sixth circuit patterns 141 may be wider than a line width W1 of each of the plurality of first circuit patterns 121 and a line width W2 of each of the plurality of second circuit patterns 122, respectively. In addition, an interval S2 between the plurality of fifth circuit patterns 131 and an interval S3 between the plurality of sixth circuit patterns 141 may be longer than an interval S1 between each of the plurality of first circuit patterns 121 and each of the plurality of second circuit patterns 122, respectively. For example, each of the plurality of fifth and sixth circuit patterns 131 and 141 may include a general circuit pattern, rather than a microcircuit pattern, for example, a general circuit pattern in which each of the line widths W5 and W6 exceeds 10 μm, and each of the intervals S2 and S3 exceeds 10 μm, and may also include a pad pattern or a plain pattern, for example, a pad pattern or a plain pattern having a width exceeding 10 μm.

The plurality of first and second circuit patterns 121 and 122 and the at least one third and fourth circuit patterns 123 and 124 may not include a seed metal layer, and the plurality of fifth circuit patterns 131 and the plurality of sixth circuit patterns 141 may include seed metal layers m1 and m2, respectively. In this manner, unlike the plurality of fifth circuit patterns 131 and the plurality of sixth circuit patterns 141 formed by the plating process of MSAP, SAP, or the like, the plurality of first and second circuit patterns 121 and 122 and the at least one third and fourth circuit patterns 123 and 124 may be formed by the above-described microcircuit formation process, and may not include a seed metal layer.

Hereinafter, components of the multilayer printed circuit boards 300A, 300B, 300C, and 300D will be described in more detail with reference to the drawings.

The second insulating layer 112 may include an insulating material. The insulating material may include a thermosetting resin such as an epoxy resin, a thermoplastic resin such as polyimide, or a material including an inorganic filler, an organic filler, and/or glass fiber (glass cloth, glass fabric) together with a resin. For example, the insulating material may be a non-photosensitive insulating material such as Ajinomoto Build-up Film (ABF), a prepreg (PPG), or the like, but is not limited thereto, and other polymer materials may be used. In addition, the insulating material may be a photosensitive insulating material such as a photoimageable dielectric (PID) or the like.

Each of the plurality of fifth and sixth circuit patterns 131 and 141 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the plurality of fifth and sixth circuit patterns 131 and 141 may perform various functions according to a design. For example, a signal pattern, a power pattern, or a ground pattern may be included. Each of these patterns may include a line pattern, a pad pattern, a plain pattern, or the like. Each of the plurality of fifth and sixth circuit patterns 131 and 141 may include an electroless plating layer (or chemical copper) and an electrolytic plating layer (or electrolytic copper), but is not limited thereto. A sputter layer may be formed, instead of the electroless plating layer, or both may be included. In addition, a copper foil may be further included.

Each of the seed metal layers m1 and m2 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the seed metal layers m1 and m2 may include an electroless plating layer (or chemical copper) and/or a sputtering layer. The sputter layer may be provided as a single layer or multiple layers.

Each of the first and second connection vias 151 and 152 may include a plurality of micro-vias. Each of the micro-vias may be a filed via filling a via hole, or may be a conformal via disposed along a wall surface of the via hole. The micro-vias may be arranged in a stacked type and/or a staggered type. Each of the micro-vias may have a tapered shape in which a width of an upper surface is narrower than a width of a lower surface. The first and second connection vias 151 and 152 may include a metal, and the metal may include copper (Cu), aluminum (Al), silver (Ag), tin (Sn), gold (Au), nickel (it may include Ni), lead (Pb), titanium (Ti), or alloys thereof, or the like, and preferably may include copper (Cu), but is not limited thereto. Each of the first and second connection vias 151 and 152 may include an electroless plating layer (or chemical copper) and an electrolytic plating layer (or electrolytic copper), but is not limited thereto. A sputter layer may be formed, instead of the electroless plating layer, or both may be included. Each of the first and second connection vias 151 and 152 may perform various functions according to a design of the corresponding layer. For example, a ground via, a power via, a signal via, or the like may be included.

The first and second resist layers 161 and 162 may include a liquid- or film-type solder resist, but is not limited thereto, and other types of insulating materials may be used. The first resist layer 161 may have first and/or second openings h1 and/or h3 exposing at least a portion of at least one of the at least one third circuit pattern 123 and/or at least a portion of at least one of the at least one fourth circuit pattern 124. The second resist layer 162 may have a third opening h2 exposing at least a portion of at least one of the plurality of sixth circuit patterns 141. A surface treatment layer may be formed on a pattern exposed through the first opening h1, the second opening h3, and/or the third opening h2. Alternatively, a metal bump may be formed on the pattern exposed through the first opening h1, the second opening h3, and/or the third opening h2. A depth of the second opening h3 may be deeper than a depth of the first opening h1.

As necessary, the multilayer printed circuit boards 300A, 300B, 300C, and 300D may include a greater number of insulating layers, wiring layers, and connection via layers, as compared to those illustrated in the drawings, and, for example, the components may be added between the first and second insulating layers 111 and 112.

Since others may be substantially the same as those described in the above-described printed circuit boards 100A, 100B, 100C, and 100D, overlapping description thereof will be omitted.

The multilayer printed circuit boards 300A, 300B, 300C, and 300D may further include, after forming a first insulating layer 111, forming a second wiring layer 130 on the first insulating layer 111, forming a first connection via 151 passing through the first insulating layer 111 and connected to at least a portion of the second wiring layer 130, forming a second insulating layer 112 covering at least a portion of the second wiring layer 130 on the first insulating layer 111, forming a third wiring layer 140 on the second insulating layer 112, and forming a second connection via 152 passing through the second insulating layer 112 and connected to at least a portion of the third wiring layer 140, as compared to the manufacturing methods described in FIGS. 7A to 7K and FIGS. 8A to 8D. As necessary, after etching a remaining portion of a metal layer 231, forming a first resist layer 161 covering at least a portion of a plurality of first metal patterns 221, at least a portion of a plurality of second metal patterns 222, at least a portion of at least one third metal pattern 223, and at least a portion of at least one fourth metal pattern 224, on the first insulating layer 111, and forming a second resist layer 162 covering at least a portion of the third wiring layer 140 on the second insulating layer 112, may be further included.

The second insulating layer 112, the second and third wiring layers 130 and 140, and the first and second connection vias 151 and 52 may be formed by a build-up process. For example, the second insulating layer 112 may be formed by stacking and curing an uncured film, but is not limited thereto. In addition, the second and third wiring layers 130 and 140 and the first and second connection vias 151 and 152 may be formed by processing via holes in the first and second insulating layers 111 and 112, and then by a plating process using SAP, MSAP, or the like, but is not limited thereto.

Since others may be substantially the same as those described in the manufacturing method described in FIGS. 7A to 7K and FIGS. 8A to 8D described above, overlapping descriptions thereof will be omitted.

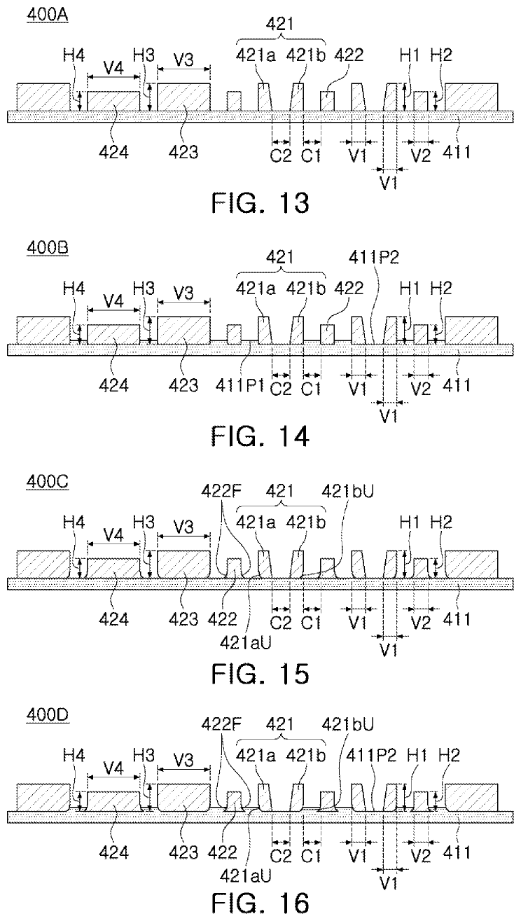

FIG. 13 is a cross-sectional view schematically illustrating another example of a printed circuit board.

Referring to the drawings, a printed circuit board 400A according to another example may include a first insulating layer 411, a plurality of first circuit patterns 421a and 421b respectively disposed on the first insulating layer 411, and a plurality of second circuit patterns 422 respectively disposed on the first insulating layer 411. A thickness H1 of each of the plurality of first circuit patterns 421a and 421b may be thicker than a thickness H2 of each of the plurality of second circuit patterns 422. A pair of first circuit patterns 421, among the plurality of first circuit patterns 421a and 421b, may be alternately and repeatedly disposed with one second circuit pattern 422 among the plurality of second circuit patterns 422. The alternate and repeated arrangement may be referred to as being alternately arranged at least twice, for example, a second circuit pattern 422, a 1-1 circuit pattern 421a, a 1-2 circuit pattern 421b, a second circuit pattern 422, a 1-1 circuit pattern 421a, a 1-2 circuit pattern 421b, a second circuit pattern 422, and the like may be arranged on the first insulating layer 411 in cross-sectional view. The number of alternately and repeatedly arranged first and second circuit patterns 421a, 421b, and 422 is not particularly limited, and may be changed according to a design. One side surfaces of the pair of first circuit patterns 421, facing each other, may be inclined to substantially reduce an interval between the one side surfaces toward the first insulating layer 111. The other side surface of the pair of first circuit patterns 421 may be substantially vertical. In this repetitive arrangement, a line width V1 of each of the pair of first circuit patterns 421, a line width V2 of the one second circuit pattern 422, an interval C1 between each of the pair of first circuit patterns 421 and the one second circuit pattern 422, and an interval C2 between the pair of first circuit patterns 421 may be substantially equal to each other. In one example, the line width V1 of each of the pair of first circuit patterns 421 may refer to a line width of a bottom portion of each of the pair of first circuit patterns 421, or alternatively, the line width V1 of each of the pair of first circuit patterns 421 may refer to a line width of a widest portion of each of the pair of first circuit patterns 421. In one example, the interval C2 between the pair of first circuit patterns 421 may refer to an interval of bottom portions of the pair of first circuit patterns 421 or a narrowest interval between the pair of first circuit patterns 421.

The plurality of first and second circuit patterns 421a, 421b, and 422 may be microcircuit patterns. For example, each of the plurality of first and second circuit patterns 421a, 421b, and 422 may have respective line widths V1 and V2 of 10 μm or less, 5 μm or less, or 2 μm or less. In addition, the intervals C1 and C2 between the plurality of first and second circuit patterns 421a, 421b, and 422 may be 10 μm or less, 5 μm or less, or 2 μm or less, respectively. For example, in the plurality of first and second circuit patterns 421a, 421b, and 422, microcircuit patterns may have a line/space of 10 μm/10 μm or less, 5 μm/5 μm or less, or 2 μm/2 μm or less, respectively.

A printed circuit board 400B according to another example of such a structure may be formed by a new process to be described later, and in this case, unlike conventional SAP, MSAP, or the like, it is possible to overcome limitation of resolution of exposure equipment, and a separate seed etching process may not be performed, and as a result, a microcircuit pattern having an L/S of 10 μm/10 μm or less, 5 μm/5 μm or less, or 2 μm/2 μm or less may be easily formed.

A printed circuit board 400B according to another example may further include at least one third circuit pattern 423 disposed on the first insulating layer 411 and having a width or a line width V3, respectively wider than the line width V1 of each of the plurality of first circuit patterns 421a and 421b and the line width V2 of each of the plurality of second circuit patterns 422. The at least one third circuit pattern 423 may include a general circuit pattern, not a microcircuit pattern, for example, a general circuit pattern having a line width and an interval therebetween exceeding 10 μm, and/or a pad pattern, for example, a pad pattern having a width exceeding 10 μm.

A printed circuit board 400B according to another example may further include at least one fourth circuit pattern 424 disposed on the first insulating layer 411 and having a width or a line width V4, respectively wider than the line width V1 of each of the plurality of first circuit patterns 421a and 421b and the line width V2 of each of the plurality of second circuit patterns 422. A thickness H4 of the at least one fourth circuit pattern 424 may be less than a thickness H3 of the at least one third circuit pattern 423. The at least one fourth circuit pattern 424 may include a general circuit pattern, not a microcircuit pattern, for example, a general circuit pattern having a line width and an interval therebetween exceeding 10 μm, and/or a plain pattern, for example, a plain pattern having a width exceeding 10 μm.

Hereinafter, components of a printed circuit board 400B according to an example will be described in more detail with reference to the drawings.

The first insulating layer 411 may include an insulating material. The insulating material may include a thermosetting resin such as an epoxy resin, a thermoplastic resin such as polyimide, or a material including an inorganic filler, an organic filler, and/or glass fiber (glass cloth, glass fabric) together with a resin. For example, the insulating material may be a non-photosensitive insulating material such as Ajinomoto Build-up Film (ABF), a prepreg (PPG), or the like, but is not limited thereto, and other polymer materials may be used. In addition, the insulating material may be a photosensitive insulating material such as a photoimageable dielectric (PID) or the like.

Each of the plurality of first and second circuit patterns 421a, 421b, and 422 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the plurality of first and second circuit patterns 421a, 421b, and 422 may perform various functions according to a design. For example, a signal pattern may be included. Each of the plurality of first and second circuit patterns 421a, 421b, and 422 may not include a separate seed metal layer. For example, each of the plurality of first and second circuit patterns 421a, 421b, and 422 may include an electrolytic plating layer (or electrolytic copper), and may not include an electroless plating layer (or chemical copper) or a sputter layer.

Each of the at least one third and fourth circuit patterns 423 and 424 may include a metal. The metal may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but is not limited thereto. Each of the at least one third and fourth circuit patterns 423 and 424 may perform various functions according to a design. For example, a signal pattern, a power pattern, or a ground pattern may be included. Each of these patterns may include a line pattern, a pad pattern, a plain pattern, or the like. Each of the at least one third and fourth circuit patterns 423 and 424 may not include a separate seed metal layer. For example, each of the at least one third and fourth circuit patterns 423 and 424 may include an electrolytic plating layer (or electrolytic copper), and may not include an electroless plating layer (or chemical copper) or a sputter layer.

FIGS. 14 to 16 are cross-sectional views schematically illustrating modified examples of the printed circuit board of FIG. 13.

Referring to FIG. 14, in a printed circuit board 400B according to a modified example, a portion 411P1 of a first insulating layer 411 may protrude and be disposed between at least one of a plurality of first circuit patterns 421a and 421b, and at least one of a plurality of second circuit patterns 422, as compared to a printed circuit board 400A according to another example. For example, in the above-described repeated arrangement, in cross-sectional view, a portion 411P1 of the first insulating layer 411 may protrude and be disposed between at least one of one side surface or the other side surface of each pair of first circuit patterns 421 and one side surface or the other side surface of each of one second circuit pattern 422. In this case, connection reliability between the first insulating layer 411 and the plurality of first and second circuit patterns 421a, 421b, and 422 may be further improved. The portion 411P1 of the first insulating layer 411 may also protrude and be disposed between at least one of each of the plurality of first circuit patterns 421a and 421b or each of the plurality of second circuit patterns 422 and at least one of the at least one third circuit patterns 423 or the at least one fourth circuit patterns 424, and/or may protrude and be disposed between the at least one third and fourth circuit patterns 423 and 424. In this case, connection reliability between the first insulating layer 411 and the at least one third and fourth circuit patterns 423 and 424 may be further improved. A different portion 411P2 of the first insulating layer 411, for example, in the above-described repeated arrangement, in cross-sectional view, the different portion 411P2 disposed between one side surfaces of the pair of first circuit patterns 421 may not protrude between the one side surfaces of the pair of first circuit patterns 421, and, thus, may have a step difference with the above-described portion 411P1.

Referring to FIG. 15, in a printed circuit board 400C according to another modified example, an undercut may be formed on at least a portion of each lower side of a plurality of first circuit patterns 421a and 421b, and a foot may be formed on at least a portion of each lower side of a plurality of second circuit patterns 422, as compared to a printed circuit board 400A according to an example. For example, in the above-described repeated arrangement, in cross-sectional view, each pair of first circuit patterns 421 may have grooves 421aU and 421bU on lower sides of the other side surfaces, and one second circuit pattern 422 may have protrusions 422F on lower sides of both side surfaces. In this case, connection reliability between a first insulating layer 411 and the plurality of first and second circuit patterns 421a, 421b, and 422 may be further improved. The undercut may also be formed on at least a portion of a lower side of at least one third circuit pattern 423, and the foot may also be formed on at least a portion of a lower side of at least one fourth circuit pattern 424. In this case, connection reliability between the first insulating layer 411 and the at least one third and fourth circuit patterns 423 and 424 may be further improved.

Referring to FIG. 16, in a printed circuit board 400D according to another modified example, a portion 411P1 of a first insulating layer 411 may protrude and be disposed between at least one of a plurality of first circuit patterns 421a and 421b, and at least one of a plurality of second circuit patterns 422, as compared to a printed circuit board 400A according to an example. In addition, an undercut may be formed on at least a portion of a lower side of each of the plurality of first circuit patterns 421a and 421b, and a foot may be formed on at least a portion of a lower side of each of the plurality of second circuit patterns 422. A specific structure and effect thereof may be as described above. The portion 411P1 of the first insulating layer 411 may also protrude and be disposed between at least one of each of the plurality of first circuit patterns 421a and 421b or each of the plurality of second circuit patterns 422 and at least one of at least one third circuit pattern 423 or at least one fourth circuit pattern 424, and/or may protrude and be disposed between the at least one third and fourth circuit patterns 423 and 424. In addition, the undercut may also be formed on at least a portion of a lower side of the at least one third circuit pattern 423, and the foot may also be formed on at least a portion of a lower side of the at least one fourth circuit pattern 424. A specific structure and effect thereof may be as described above. A different portion 411P2 of the first insulating layer 411, for example, in the above-described repeated arrangement, in cross-sectional view, the different portion 411P2 disposed between one side surfaces of each pair of first circuit patterns 421 may not protrude between the one side surfaces of each of the pair of first circuit patterns 421, and, thus, may have a step difference with the above-described portion 411P1.

Since others may be substantially the same as those described in the printed circuit board 400A according to the other example described above, overlapping description thereof will be omitted.

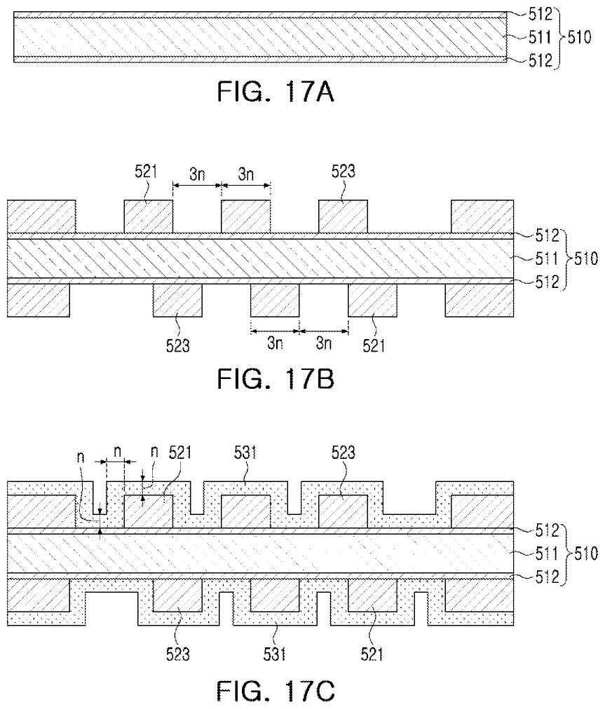

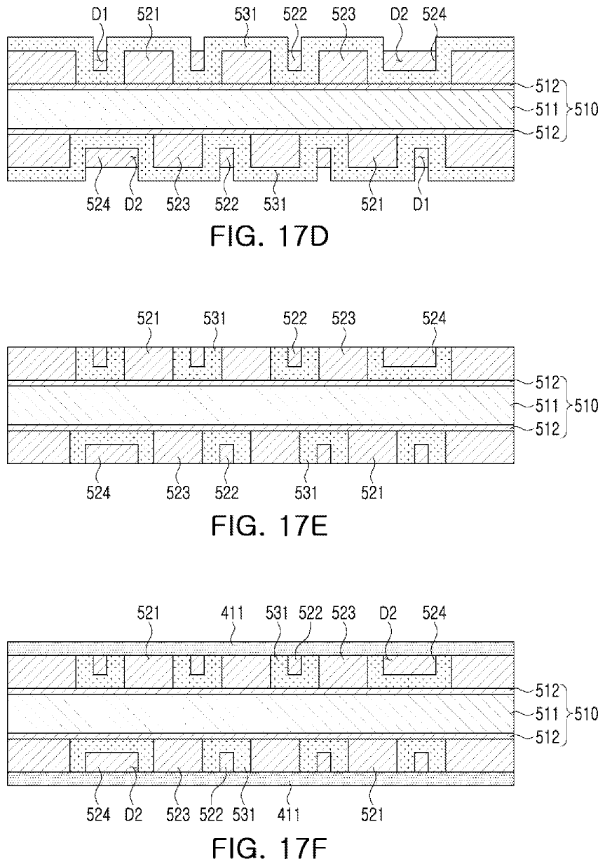

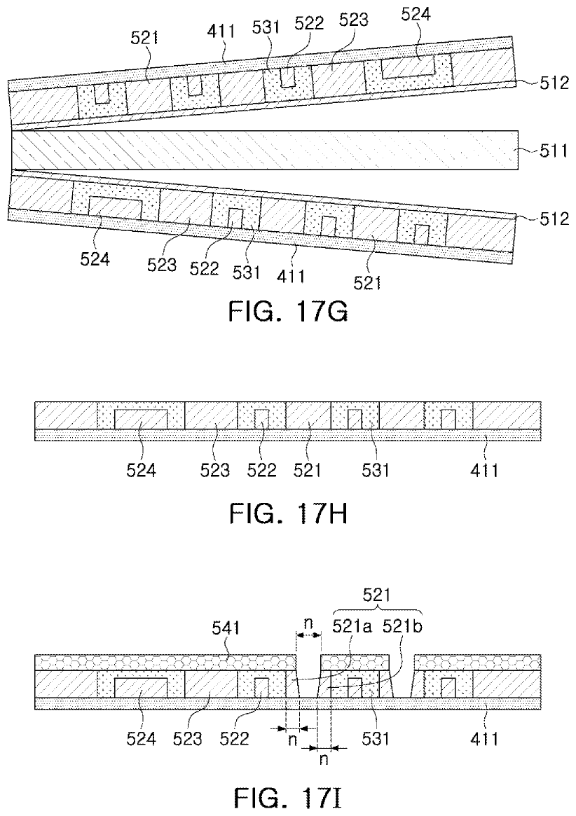

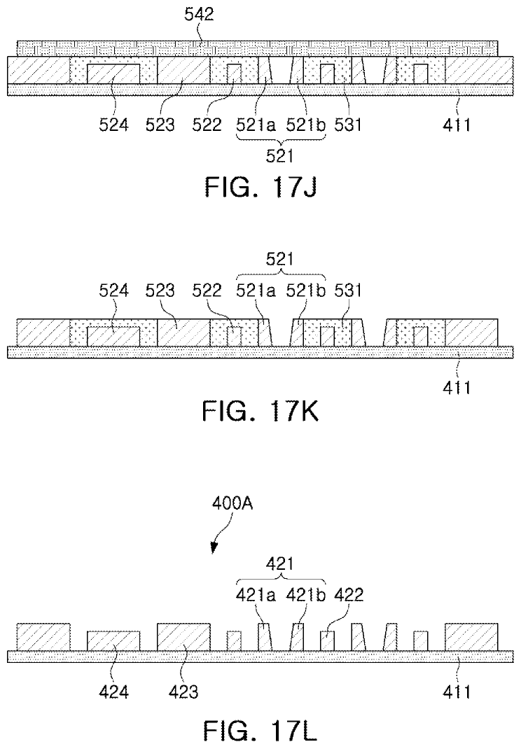

FIGS. 17A to 17L are process cross-sectional views schematically illustrating an example of manufacturing the printed circuit board of FIG. 13.

Referring to the drawings, a method of manufacturing a printed circuit board 400A according to another example may include forming a plurality of first metal patterns 521 on a substrate 510, forming a metal layer 531 covering the plurality of first metal patterns on the substrate 510, and including a metal, different from that of the plurality of first metal patterns 521, forming a plurality of second metal patterns 522 on the metal layer 531, filling at least a portion of a space D1 between external side surfaces of the metal layer 531, and including a metal, different from the metal of the metal layer 531, respectively, etching a portion of the metal layer 531 to expose at least a portion of each of the plurality of first metal patterns 521 from the metal layer 531, forming a first insulating layer 411 on the plurality of first metal patterns 521 and the plurality of second metal patterns 522, removing the substrate 510, etching each of the metal patterns 521 to divide each of the plurality of first metal patterns 521 into at least two first metal patterns 521a and 521b, and etching a remaining portion of the metal layer 531. The metal layer 531 may include metal, different from the plurality of first and second metal patterns 521 and 522. For example, the metal layer 531 may have a different etching ratio with respect to an etching solution for etching the metal layer 531, as compared to the plurality of first and second metal patterns 521 and 522. For example, the plurality of first and second metal patterns 521 and 522 may include copper (Cu), and the metal layer 531 may include nickel (Ni), but is not limited thereto.

In the forming a plurality of first metal patterns 521, if a width of each of the plurality of first metal patterns 521 is 3n, an interval between the plurality of first metal patterns 521 may substantially satisfy 3n, respectively. Also, in the forming a metal layer 531, a thickness or a width of the metal layer 531 may substantially satisfy n. In addition, in the dividing each of the plurality of first metal patterns 521 into at least two first metal patterns 521a and 521b, a width of each of the at least two first metal patterns 521a and 521b of the plurality of first metal patterns 521 may substantially satisfy n. Therefore, a microcircuit having an L/S of n/n may be finally formed. In this manner, even if a width and an interval of an initial metal pattern are respectively 3n, a line width and an interval of a final microcircuit may be formed to be n, respectively.

Since a printed circuit board 400A according to another example formed by such a manufacturing method may form an interval between first metal patterns with ease, as described above, and unlike conventional SAP, MSAP, or the like, it is possible to overcome a limitation of resolution of exposure equipment, and a separate seed etching process may not be performed, and as a result, a microcircuit pattern having an L/S of 10 μm/10 μm or less, or 5 μm/5 μm or less, or 2 μm/2 μm or less may be easily formed.

A method of manufacturing a printed circuit board 400A according to an example may further include forming at least one third metal pattern 523 on the substrate 510. The at least one third metal pattern 523 may be formed together, when forming the plurality of first metal patterns 521. The at least one third metal pattern 523 may include metal, different from metal of the metal layer 531. For example, the at least one third metal pattern 523 may include copper (Cu), but is not limited thereto.

A method of manufacturing a printed circuit board 400A according to an example may further include forming at least one fourth circuit pattern 524 filling at least a portion of a different space D2 between external side surfaces of the metal layer 531, respectively. The at least one fourth metal pattern 524 may include metal, different from metal of the metal layer 531. For example, the at least one fourth metal pattern 524 may include copper (Cu), but is not limited thereto.

A method of manufacturing a printed circuit board 400A according to an example may further include, after the removing the substrate 410, forming a dry film 542 exposing a portion of at least one of the plurality of first metal patterns 521, the plurality of second metal patterns 522, the at least one third metal pattern 523, or the at least one fourth metal pattern 524, on the plurality of first metal patterns 521, the plurality of second metal patterns 522, the at least one third metal pattern 523, and the at least one fourth metal pattern 524; and etching an exposed portion of at least one of the plurality of first metal patterns 521, the plurality of second metal patterns 522, the at least one third metal pattern 523, or the at least one fourth metal pattern 524. The above operations may be performed before or after the dividing each of the plurality of first metal patterns 521 into at least two first metal patterns 521a and 521b. Through this, a portion connected to each other, an unnecessary portion, or the like, among the plurality of first metal patterns 521, the plurality of second metal patterns 522, the at least one third metal pattern 523, and/or the at least one fourth metal pattern 524, may be removed.

Hereinafter, a method of manufacturing a printed circuit board 400A according to another example will be described in more detail with reference to the drawings.

Referring to FIG. 17A, a substrate 510 may be prepared. The substrate 510 may be a copper clad laminate (CCL), but is not limited thereto, and various types of detachable carrier substrates may be used. The substrate 510 may include a detachable core 511 and a detachable metal layer 512. The detachable metal layer 512 may be disposed on one surface or both side surfaces of the detachable core 511. The detachable core 511 may include an insulating material, for example, an epoxy resin impregnated with glass fiber, and the detachable metal layer 512 may include metal, for example, copper (Cu). As necessary, a releaseable layer may be further disposed between the detachable core 511 and the detachable metal layer 512.

Referring to FIG. 17B, a plurality of first metal patterns 521 may be formed on the substrate 510. In this case, at least one third metal pattern 523 may be further formed. The plurality of first metal patterns 521 and the at least one third metal pattern 523 may form a dry film including a photosensitive insulating material on the substrate 510, a pattern opening may be formed in the dry film by a photolithography process, for example, an exposure and development process, and the detachable metal layer 512 exposed through the pattern opening as a seed metal layer may be formed by filling at least a portion of the pattern opening by a plating process, for example, electrolytic plating (as electrolytic copper). The at least one third metal pattern 523 may include metal, identical to metal of the plurality of first metal patterns 521, for example, copper (Cu). If the width of each of the plurality of first metal patterns 521 is 3n, an interval between the plurality of first metal patterns 521 may substantially satisfy 3n.

Referring to FIG. 17C, a metal layer 531 covering the plurality of first metal patterns 521 and the at least one third metal pattern 523 may be formed on the plurality of first metal patterns 521 and the at least one third metal pattern 523. The metal layer 531 may be formed by a plating process, for example, electrolytic plating (as electrolytic copper). The metal layer 531 may include metal, different from the plurality of first metal patterns 521 and the at least one third metal pattern 523, for example, nickel (Ni). If the width of each of the plurality of first metal patterns 521 is n, a thickness or a width of the metal layer 531 may substantially satisfy n.

Referring to FIG. 17D, a plurality of second metal patterns 522 filling at least a portion of a space D1 between external side surfaces of the metal layer 531 may be formed on the metal layer 531. In this case, at least one fourth metal pattern 524 filling at least a portion of a different space D2 between external side surfaces of the metal layer 531 may be further formed on the metal layer 531. The plurality of second metal patterns 522 and the at least one fourth metal pattern 524 may be formed by filling at least a portion of the space D1 and at least a portion of the spaces D2 by a plating process, for example, electrolytic plating (as electrolytic copper). The at least one fourth metal pattern 524 may include the same metal as the plurality of second metal patterns 522, for example, copper (Cu). If the width of each of the plurality of first metal patterns 521 is 3n, a width of each of the plurality of second metal patterns 522 may substantially satisfy n.

Referring to FIG. 17E, at least a portion of each of the plurality of first metal patterns 521 and at least a portion of each of the at least one third metal pattern 523 may be exposed from the metal layer 531 by etching a portion of the metal layer 531. The metal layer 531 may include a metal, different from the metal of the plurality of first metal patterns 521 and the metal of the at least one third metal pattern 523, for example, nickel (Ni), and may thus be selectively etched with an etching solution for nickel (Ni). The etching solution for nickel (Ni) may use an etching ratio of at least 8:2 or more between nickel (Ni) and copper (Cu).

Referring to FIG. 17F, a first insulating layer 411 may be formed on the plurality of first and second metal patterns 521 and 522 and the at least one third and fourth metal patterns 523 and 524. The first insulating layer 411 may be formed by stacking and curing an uncured film, but is not limited thereto.

Referring to FIGS. 17G and 17H, the substrate 510 may be removed. The detachable core 511 may be separated and removed from the detachable metal layer 512. The detachable metal layer 512 remaining after the separation and removal of the detachable core 511 may be etched and removed.

Referring to FIG. 17I, each of the plurality of first metal patterns 521 may be etched to divide each of the plurality of first metal patterns 521 into at least two first metal patterns 521a and 521b. As an etching method, tenting may be used, for example. For example, a first dry film 541 having an opening exposing a central portion of each of the plurality of first metal patterns 521 may be formed on the plurality of first and second metal patterns 521 and 522 and the at least one third and fourth metal patterns 523 and 524, and an exposed portion of each of the plurality of first metal patterns 521 may be etched to divide the plurality of first metal patterns 521 into the at least two first metal patterns 521a and 521b. The opening of the first dry film 541 may be formed by a photolithography process, for example, an exposure and development process. The opening of the first dry film 541 may substantially satisfy n, and thus, a width of each of the at least two first metal patterns 521a and 521b of the plurality of first metal patterns 521 may substantially satisfy n.

Referring to FIGS. 17J and 17K, a second dry film 542 exposing a portion of at least one of the plurality of first and second metal patterns 521 and 522 or the at least one third and fourth metal patterns 523 and 524 may be formed on the plurality of first and second metal patterns 521 and 522 and the at least one third and fourth metal patterns 523 and 524, and then an exposed portion of at least one of the plurality of first and second metal patterns 521 and 522 or the at least one third and fourth metal patterns 523 and 524 may be formed. The opening of the second dry film 542 may be formed by a photolithography process, for example, an exposure and development process. The above operations may be performed before or after the dividing each of the plurality of first metal patterns 521 into at least two first metal patterns 521a and 521b. Through this, a portion connected to each other, an unnecessary portion, or the like, among the plurality of first metal patterns 521, the plurality of second metal patterns 522, the at least one third metal pattern 523, and/or the at least one fourth metal pattern 524, may be removed.

Referring to FIG. 17L, a remaining portion of the metal layer 531 may be etched. A plurality of first circuit patterns 421a and 421b, a plurality of second circuit patterns 422, at least one third circuit pattern 423, and at least one fourth circuit pattern 424 may be formed from the plurality of first metal patterns 521, the plurality of second metal patterns 522, the at least one third metal pattern 523, and the at least one fourth metal pattern 524 by etching the metal layer 531.

Since the printed circuit board 400A according to the above-described example may be formed by a series of processes, and others may be substantially the same as those described in the printed circuit board 400A according to the above-described example, overlapping description thereof will be omitted.

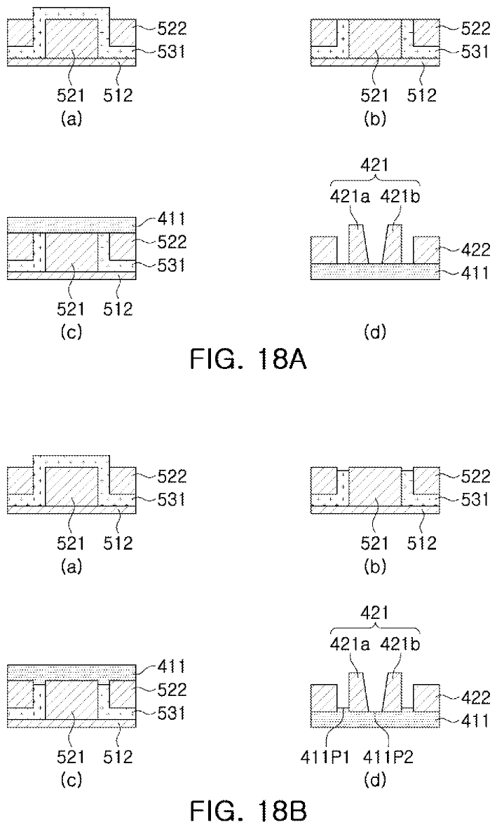

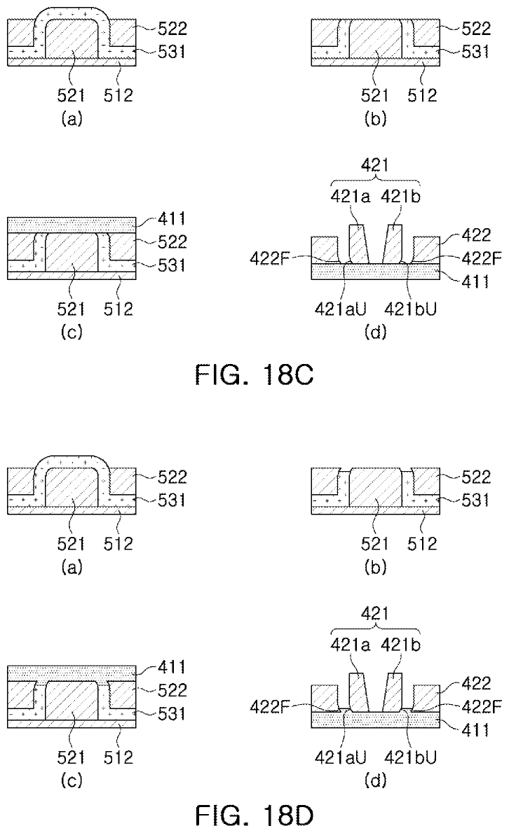

FIGS. 18A to 18D are process cross-sectional views schematically illustrating shapes of a plurality of first metal patterns, a plurality of second metal patterns, and a plurality of metal layers, and etching degrees of some of the metal layers, for manufacturing the printed circuit boards of FIGS. 13 to 16, respectively.

Referring to FIG. 18A, as in (a), at least a portion of an edge of each top surface of a plurality of first metal patterns 521 may be formed substantially vertically, and, thus, at least a portion of an edge of a top surface of a metal layer 531, and at least a portion of an edge of each top surface of a plurality of second metal patterns 522 may be formed substantially vertically. In this case, at least a portion of an edge of a top surface of at least one third metal pattern 523 and at least a portion of an edge of a top surface of at least one fourth metal pattern 524 may be formed substantially vertically. In addition, as in (b), when the metal layer 531 is selectively removed, the top surface of the metal layer 531 may be etched to be substantially coplanar with the top surface of each of the plurality of first and second metal patterns 521 and 522. In this case, the top surface of the metal layer 531 may also be etched to be substantially coplanar with the top surface of each of the at least one third and fourth metal patterns 523 and 524. Therefore, as in (c), a first insulating layer 411 may be formed on the substantially coplanar surface. Also, as in (d), an undercut or a foot may not be formed on a bottom side of each of the plurality of first and second circuit patterns 421a, 421b, and 422. In this case, the undercut or the foot may not be formed on a bottom side of the at least one third and fourth circuit patterns 423 and 424. In addition, a top surface of the first insulating layer 411 may be substantially flat without a step difference. For example, a structure of a printed circuit board 400A according to an example may be formed.

Referring to FIG. 18B, unlike in FIG. 18A, in (b), when a metal layer 531 is selectively removed, the metal layer 531 may be excessively etched, and a top surface of the metal layer 531 may be etched to have a step difference with each top surface of a plurality of first metal patterns 521 and each top surface of a plurality of second metal patterns 522. In this case, the metal layer 531 may also be etched to have a step difference with a top surface of at least one third metal pattern 523 and a top surface of at least one fourth metal pattern 524. Therefore, in (c), the first insulating layer 411 may extend to reach the excessively etched region. Also, in (d), a portion 411P1 of the first insulating layer 411 may protrude between the plurality of first and second circuit patterns 421a, 421b, and 422. In this case, the portion 411P1 of the first insulating layer 411 may also protrude between the at least one third and fourth circuit patterns 423 and 424, or the like. For example, a structure of a printed circuit board 400B according to a modified example may be formed.

Referring to FIG. 18C, unlike in FIG. 18A, in (a), at least a portion of an edge of each top surface of a plurality of first metal patterns 521 may be formed to be rounded. Therefore, at least a portion of an edge of a top surface of a metal layer 531 may be formed to be rounded, and at least a portion of an edge of each top surface of a plurality of second metal patterns 522 may be formed to be pointed. In this case, at least a portion of an edge of a top surface of at least one third metal pattern 523 and at least a portion of an edge of a top surface of at least one fourth metal pattern 524 may also be formed to be rounded or pointed. Therefore, in (d), an undercut or a foot, for example, grooves 421aU and 421bU and a protrusion 422F may be formed on at least a portion of a bottom side of each of the plurality of first and second circuit patterns 421a, 421b, and 422. In this case, the undercut or the foot may also be formed on at least a portion of a bottom side of each of the at least one third and fourth circuit patterns 423 and 424. For example, a structure of a printed circuit board 400C according to another modified example may be formed.

Referring to FIG. 18D, unlike in FIG. 18A, in (a), at least a portion of an edge of each top surface of a plurality of first metal patterns 521 may be formed to be rounded. Therefore, at least a portion of an edge of a top surface of a metal layer 531 may be formed to be rounded, and at least a portion of an edge of each top surface of a plurality of second metal patterns 522 may be formed to be pointed. In this case, at least a portion of an edge of a top surface of at least one third metal pattern 523 and at least a portion of an edge of a top surface of at least one fourth metal pattern 524 may also be formed to be rounded or pointed. In addition, when the metal layer 531 is selectively removed in (b), the metal layer 531 may be excessively etched, such that the top surface of the metal layer 231 has a step difference with the top surface of each of the plurality of first and second metal patterns 521 and 522. In this case, the metal layer 531 may also be etched to have a step difference with the top surface of each of the at least one third and fourth metal patterns 523 and 524. Therefore, in (c), the first insulating layer 411 may extend to reach the excessively etched region. Also, in (d), a portion 411P1 of the first insulating layer 411 may protrude between the plurality of first and second circuit patterns 421a, 421b, and 422. In this case, the portion 411P1 of the first insulating layer 411 may also protrude between the at least one third and fourth circuit patterns 423 and 424, or the like. In addition, an undercut or a foot, for example, grooves 421aU and 421bU and a protrusion 422F may be formed on at least a portion of a bottom side of each of the plurality of first and second circuit patterns 421a, 421b, and 422. In this case, the undercut or the foot may also be formed on at least a portion of a bottom side of each of the at least one third and fourth circuit patterns 423 and 424. For example, a structure of a printed circuit board 400D according to another modified example may be formed.

Since others may be substantially the same as those described in the above-described printed circuit boards 400A, 400B, 400C, and 400D and the manufacturing method of the above-described printed circuit board 400A, overlapping description thereof will be omitted.

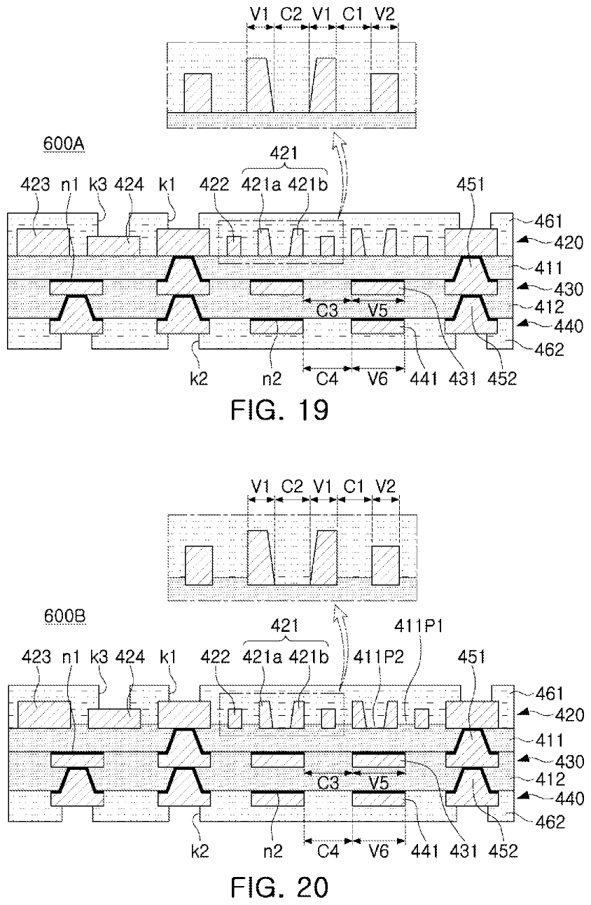

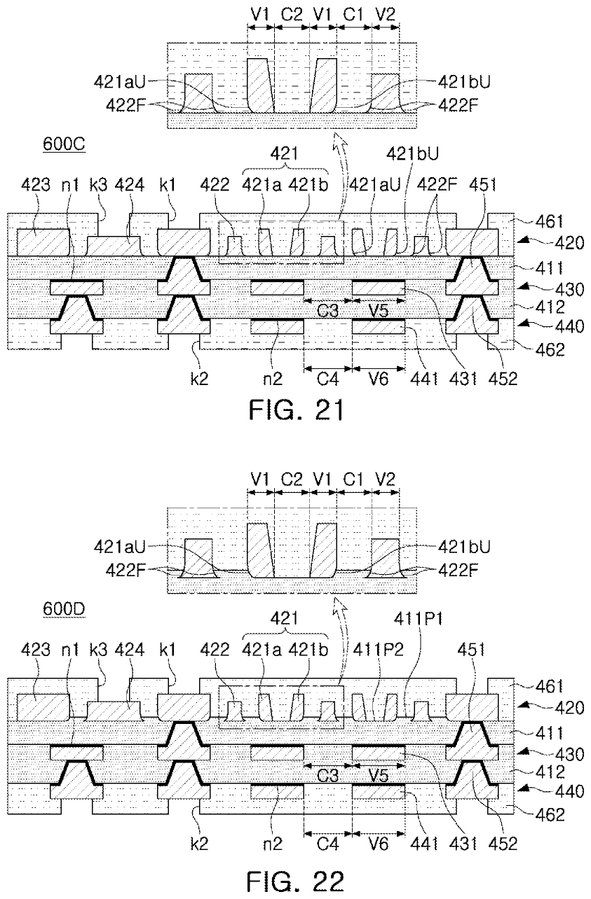

FIGS. 19 to 22 are cross-sectional views schematically illustrating cases in which the printed circuit boards of FIGS. 13 to 16 are applied to a multilayer printed circuit board.

Referring to the drawings, multilayer printed circuit boards 600A, 600B, 600C, and 600D may further include a first wiring layer 420 disposed on an upper surface of a first insulating layer 411, and including a plurality of first circuit patterns 421a and 421b, a plurality of second circuit patterns 422, at least one third circuit pattern 423, and at least one third circuit pattern 424; a second wiring layer 430 disposed on a lower surface of the first insulating layer 411, and including a plurality of fifth circuit patterns 431; a first connection via 451 passing through the first insulating layer 411 and connected to at least a portion of the second wiring layer 430; a second insulating layer 412 disposed on the lower surface of the first insulating layer 411 and covering at least a portion of the second wiring layer 430; a third wiring layer 440 disposed on a lower surface of the second insulating layer 412 and including a plurality of sixth circuit patterns 441; and a second connection via 452 passing through the second insulating layer 412 and connected to at least a portion of the third wiring layer 440, as compared to the above-described printed circuit boards 400A, 400B, 400C, and 400D. As necessary, a first resist layer 461 disposed on the upper surface of the first insulating layer 411 and covering at least a portion of the first wiring layer 420, and a second resist layer 462 disposed on the lower surface of the second insulating layer 412 and covering at least a portion of the third wiring layer 440, may be further included.

A width or a line width V5 of each of the plurality of fifth circuit patterns 431 and a width or a line width V6 of each of the plurality of sixth circuit patterns 441 may be wider than a line width V1 of each of the plurality of first circuit patterns 421 and a line width V2 of each of the plurality of second circuit patterns 422, respectively. In addition, an interval C3 between the plurality of fifth circuit patterns 431 and an interval C4 between the plurality of sixth circuit patterns 441 may be longer than an interval (C1 and C2) between each of the plurality of first circuit patterns 421a and 421b and each of the plurality of second circuit patterns 422, respectively. For example, each of the plurality of fifth and sixth circuit patterns 431 and 441 may include a general circuit pattern, rather than a microcircuit pattern, for example, a general circuit pattern in which each of the line widths V5 and V6 exceeds 10 μm, and each of the intervals C3 and C4 exceeds 10 μm, and may also include a pad pattern or a plain pattern, for example, a pad pattern or a plain pattern having a width exceeding 10 μm.

The plurality of first and second circuit patterns 421a, 421b, and 422 and the at least one third and fourth circuit patterns 423 and 424 may not include a seed metal layer, and the plurality of fifth circuit patterns 431 and the plurality of sixth circuit patterns 441 may include seed metal layers n1 and n2, respectively. In this manner, unlike the plurality of fifth circuit patterns 431 and the plurality of sixth circuit patterns 441 formed by the plating process of MSAP, SAP, or the like, the plurality of first and second circuit patterns 421a, 421b, and 422 and the at least one third and fourth circuit patterns 423 and 424 may be formed by the above-described microcircuit formation process, and may not include a seed metal layer. In one example, the seed metal layers n1 and n2 may respectively extend on wall surfaces of via holes in which the first connection via 451 and the second connection via 452 are respectively disposed. The seed metal layers n1 and n2 may also respectively extend in the via holes as a bottom of the via holes.

Hereinafter, components of the multilayer printed circuit boards 600A, 600B, 600C, and 600D will be described in more detail with reference to the drawings.

The second insulating layer 412 may include an insulating material. The insulating material may include a thermosetting resin such as an epoxy resin, a thermoplastic resin such as polyimide, or a material including an inorganic filler, an organic filler, and/or glass fiber (glass cloth, glass fabric) together with a resin. For example, the insulating material may be a non-photosensitive insulating material such as Ajinomoto Build-up Film (ABF), a prepreg (PPG), or the like, but is not limited thereto, and other polymer materials may be used. In addition, the insulating material may be a photosensitive insulating material such as a photoimageable dielectric (PID) or the like.

Each of the plurality of fifth and sixth circuit patterns 431 and 441 may include a metal. The metal may include copper (Cu), aluminum (Al), silver (Ag), tin (Sn), gold (Au), nickel (Ni), lead (Pb), titanium (Ti), and/alloys thereof, or the like. Preferably, copper (Cu) may be included, but is not limited thereto. Each of the plurality of fifth and sixth circuit patterns 431 and 441 may perform various functions according to a design. For example, a signal pattern, a power pattern, or a ground pattern may be included. Each of these patterns may include a line pattern, a pad pattern, a plain pattern, or the like. Each of the plurality of fifth and sixth circuit patterns 431 and 441 may include an electroless plating layer (or chemical copper) and an electrolytic plating layer (or electrolytic copper), but is not limited thereto. A sputtering layer may be formed, instead of the electroless plating layer, or both may be included. In addition, a copper foil may be further included.

Each of the seed metal layers n1 and n2 may include a metal. The metal may include copper (Cu), aluminum (Al), silver (Ag), tin (Sn), gold (Au), nickel (Ni), lead (Pb), titanium (Ti), and/alloys thereof, or the like. Preferably, copper (Cu) may be included, but is not limited thereto. The seed metal layer (m) may include an electroless plating layer (or chemical copper) and/or a sputtering layer. The sputtering layer may be provided as a single layer or multiple layers.

Each of the first and second connection vias 451 and 452 may include a plurality of micro-vias. Each of the micro-vias may be a filed via filling a via hole, or may be a conformal via disposed along a wall surface of the via hole. The micro-vias may be arranged in a stacked type and/or a staggered type. Each of the micro-vias may have a tapered shape in which a width of an upper surface is narrower than a width of a lower surface. The first and second connection vias 451 and 452 may include a metal, and the metal may include copper (Cu), aluminum (Al), silver (Ag), tin (Sn), gold (Au), nickel (Ni), lead (Pb), titanium (Ti), alloys thereof, or the like, and preferably may include copper (Cu), but is not limited thereto. Each of the first and second connection vias 451 and 452 may include an electroless plating layer (or chemical copper) and an electrolytic plating layer (or electrolytic copper), but is not limited thereto. A sputtering layer may be formed, instead of the electroless plating layer, or both may be included. Each of the first and second connection vias 451 and 452 may perform various functions according to a design of the corresponding layer. For example, a ground via, a power via, a signal via, or the like may be included.

The first and second resist layers 461 and 462 may include a liquid- or film-type solder resist, but is not limited thereto, and other types of insulating materials may be used. The first resist layer 461 may have first and/or second openings k1 and/or k3 exposing at least a portion of at least one of the at least one third circuit pattern 423 and/or at least a portion of at least one of the at least one fourth circuit pattern 424. The second resist layer 462 may have a third opening k2 exposing at least a portion of at least one of the plurality of sixth circuit patterns 441. A surface treatment layer may be formed on a pattern exposed through the first opening k1, the second opening k3, and/or the third opening k2. Alternatively, a metal bump may be formed on the pattern exposed through the first opening k1, the second opening k3, and/or the third opening k2. A depth of the second opening k3 may be deeper than a depth of the first opening k1.

As necessary, the multilayer printed circuit boards 600A, 600B, 600C, and 600D may include a greater number of insulating layers, wiring layers, and connection via layers than those illustrated in the drawings, and, for example, the components may be added between the first and second insulating layers 411 and 412.

Since others may be substantially the same as those described in the above-described printed circuit boards 400A, 400B, 400C, and 400D, overlapping description thereof will be omitted.

The multilayer printed circuit boards 600A, 600B, 600C, and 600D may be formed by a process further including, after forming a first insulating layer 411, forming a second wiring layer 430 on the first insulating layer 411, forming a first connection via 451 passing through the first insulating layer 411 and connected to at least a portion of the second wiring layer 430, forming a second insulating layer 412 covering at least a portion of the second wiring layer 430 on the first insulating layer 411, forming a third wiring layer 440 on the second insulating layer 412, and forming a second connection via 452 passing through the second insulating layer 412 and connected to at least a portion of the third wiring layer 440, as compared to the manufacturing method described in FIGS. 17A to 17L and FIGS. 18A to 18D. As necessary, after etching a remaining portion of the metal layer 531, forming a first resist layer covering at least a portion of a plurality of first metal patterns 521, at least a portion of a plurality of second metal patterns 522, at least a portion of at least one third metal pattern 523, and at least a portion of at least one fourth metal pattern 524, on the first insulating layer 411, and forming a second resist layer 462 covering at least a portion of the third wiring layer 440 on the second insulating layer 412, may be further included.

The second insulating layer 412, the second and third wiring layers 430 and 440, and the first and second connection vias 451 and 452 may be formed by a build-up process. For example, the second insulating layer 412 may be formed by stacking and curing an uncured film, but is not limited thereto. In addition, the second and third wiring layers 430 and 440 and the first and second connection vias 451 and 452 may be formed by a plating process using SAP, MSAP, or the like, after processing via holes in the first and second insulating layers 411 and 412, but is not limited thereto.

Since others may be substantially the same as those described in the manufacturing method described in FIGS. 17A to 17L and FIGS. 18A to 18D described above, overlapping descriptions thereof will be omitted.

In the present disclosure, the expression of covering may include a case of covering at least a portion as well as a case of covering an entire portion, and may also include a case of directly covering as well as a case of indirectly covering.

In the present disclosure, the expression of filling may include not only a case of completely filling but also a case of approximately filling, and may include, for example, a case in which some intervals, voids, or the like exists.

In the present disclosure, a thickness, a width, a line width, an interval, a depth, or the like may be measured using a scanning microscope or an optical microscope based on a polished or cut cross-section of a printed circuit board. For example, they may be measured in cross-sectional view. When the thickness, the width, the line width, the interval, the depth, or the like are not constant, the thickness, the width, the line width, or the like may be compared with an average value of values measured at five (5) random points. When a side surface of a pattern has a tapered shape, a line width or a width of the pattern may be measured at five (5) random points in the thickness direction, and then an average value thereof may be used.

In the present disclosure, determination may be performed by including errors in process, positional deviations, errors in measurement, and the like, substantially occurring in a manufacturing process. For example, having substantially the same line width/thickness may include not only a case of being completely numerically identical, but also a case of having substantially similar numerical values within an error range. In addition, being substantially coplanar may include not only a case of being completely in the same plane, but also a case of being in approximately the same plane.

In the present disclosure, the same insulating material may mean not only the completely same insulating material, but also include the same type of insulating material. Therefore, a composition of the insulating material may be substantially the same, but a specific composition ratio thereof may be slightly different.

In the present disclosure, the meaning of (in) cross-sectional view may mean a cross-sectional shape when an object is vertically cut, a cross-sectional shape when the object vertically cut, or a cross-sectional shape when the object is viewed from a side-view. In addition, the meaning of (in) plan view may mean a plane shape when an object is horizontally cut, or a plane shape when the object is viewed from a top-view or bottom-view.

In the present disclosure, a lower side, a lower portion, a lower surface, or the like may be used to mean a downward direction, based on the cross-section of the drawing for convenience, and an upper side, an upper portion, an upper surface, or the like may be used to mean the opposite direction. However, the above descriptions are to define a direction for convenience of description, and the scope of the claims are not particularly limited by the description of this direction, of course, and concepts of upper and lower directions may be changed at any time.

In the present disclosure, the meaning of being connected is a concept including not only being directly connected but also being indirectly connected by an adhesive layer or the like. In addition, the meaning of being electrically connected is a concept including both a physical connection and a physical non-connection. In addition, expressions such as first, second, and the like are used to distinguish one component from another, and do not limit the order and/or importance of components. In some cases, without departing from the scope of rights, a first component may be referred to as a second component, and similarly, a second component may be referred to as a first component.

The expression “one example” used in the present disclosure does not mean the same embodiment to each other, but may be provided for emphasizing and explaining different unique features. However, the above-mentioned examples do not exclude that the above-mentioned examples are implemented in combination with the features of other examples. For example, although the description in a specific example is not described in another example, it can be understood as an explanation related to another example, unless otherwise described or contradicted by the other example.

The terms used in the present disclosure are used only to illustrate various examples and are not intended to limit the present inventive concept. Singular expressions include plural expressions unless the context clearly dictates otherwise.

As one of various effects of the present disclosure, a printed circuit board capable of forming a microcircuit and a manufacturing method thereof may be provided.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a first insulating layer;
a plurality of first circuit patterns respectively disposed on the first insulating layer; and
a plurality of second circuit patterns respectively disposed on the first insulating layer and respectively having a thickness, thinner than a thickness of each of the plurality of first circuit patterns,
wherein at least one of the plurality of first circuit patterns and at least one of the plurality of second circuit patterns are alternately and repeatedly arranged.

2. The printed circuit board of claim 1, wherein a line width of each of the plurality of first circuit patterns and a line width of each of the plurality of second circuit patterns is 10 μm or less, respectively, and
an interval between each of the plurality of first circuit patterns and each of the plurality of second circuit patterns is each 10 μm or less.

3. The printed circuit board of claim 1, wherein one first circuit pattern among the plurality of first circuit patterns and one second circuit pattern among the plurality of second circuit patterns are alternately and repeatedly arranged.

4. The printed circuit board of claim 3, wherein, in a cross-sectional view,
the one first circuit pattern has grooves on lower sides of both side surfaces of the one first circuit pattern, and
the one second circuit pattern has protrusions on lower sides of both side surfaces of the one second circuit pattern.

5. The printed circuit board of claim 4, wherein a line width of the one first circuit pattern, a line width of the one second circuit pattern, and an interval between the one first circuit pattern and the one second circuit pattern are substantially equal to each other.

6. The printed circuit board of claim 4, wherein a portion of the first insulating layer is disposed to protrude between at least one of one side surface or the other side surface of the one first circuit pattern and at least one of one side surface or the other side surface of the one second circuit pattern.

7. The printed circuit board of claim 1, wherein a pair of first circuit patterns among the plurality of first circuit patterns and one second circuit pattern among the plurality of second circuit patterns are alternately and repeatedly arranged.

8. The printed circuit board of claim 7, wherein one side surfaces of the pair of first circuit patterns, facing each other, are inclined to substantially reduce an interval between the one side surfaces toward the first insulating layer.

9. The printed circuit board of claim 8, wherein, in the cross-sectional view,
the pair of first circuit patterns have grooves on lower sides of the other side surfaces of the pair of first circuit patterns, and
the one second circuit pattern has protrusions on lower sides of both side surfaces of the one second circuit pattern.

10. The printed circuit board of claim 9, wherein a line width of each of the pair of first circuit patterns, a line width of the one second circuit pattern, an interval between each of the pair of first circuit patterns and the one second circuit pattern, and an interval between the pair of first circuit patterns are substantially equal to each other.

11. The printed circuit board of claim 9, wherein a portion of the first insulating layer is disposed to protrude between at least one of the other side surfaces of the pair of first circuit patterns and at least one of one side surface or the other side surface of the one second circuit pattern.

12. The printed circuit board of claim 11, wherein the protruding portion of the first insulating layer has a step difference with a different portion of the first insulating layer disposed between the one side surfaces of the pair of first circuit patterns.

13. The printed circuit board of claim 1, further comprising:
at least one third circuit pattern disposed on the first insulating layer and having a width or a line width, respectively wider than a line width of each of the plurality of first circuit patterns and a line width of each of the plurality of second circuit patterns; and
at least one fourth circuit pattern disposed on the first insulating layer, having a thickness, thinner than a thickness of the at least one third circuit pattern, and having a width or a line width, respectively wider than the line width of each of the plurality of first circuit patterns and the line width of each of the plurality of second circuit patterns.

14. The printed circuit board of claim 13, further comprising:
a first wiring layer disposed on an upper surface of the first insulating layer, and including the plurality of first circuit patterns, the plurality of second circuit patterns, and the at least one third circuit pattern;
a second wiring layer disposed on a lower surface of the first insulating layer, and including a plurality of fifth circuit patterns having a width or a line width, respectively wider than the line width of each of the plurality of first circuit patterns and the line width of each of the plurality of second circuit patterns;
a first connection via passing through the first insulating layer and connected to at least a portion of the second wiring layer;
a second insulating layer disposed on the lower surface of the first insulating layer and covering at least a portion of the second wiring layer;
a third wiring layer disposed on a lower surface of the second insulating layer and including a plurality of sixth circuit patterns having a width or a line width, respectively wider than the line width of each of the plurality of first circuit patterns and the line width of each of the plurality of second circuit patterns; and
a second connection via passing through the second insulating layer and connected to at least a portion of the third wiring layer.

15. The printed circuit board of claim 14, further comprising:
a first resist layer disposed on the upper surface of the first insulating layer, covering at least a portion of the first wiring layer, and having at least one of a first opening exposing at least a portion of at least one of the at least one third circuit pattern, or a second opening exposing at least a portion of at least one of the at least one fourth circuit pattern; and
a second resist layer disposed on the lower surface of the second insulating layer, covering at least a portion of the third wiring layer, and having a third opening exposing at least a portion of at least one of the plurality of sixth circuit patterns.

16. The printed circuit board of claim 15, wherein a depth of the second opening is deeper than a depth of the first opening.

17. A printed circuit board comprising:
a first insulating layer;
a first wiring layer disposed above the first insulating layer, and including a first circuit pattern and a second circuit pattern, having different thicknesses; and
a second wiring layer disposed below the first insulating layer, and including a third circuit pattern having a line width, respectively wider than a line width of the first circuit pattern and a line width of the second circuit pattern.

18. The printed circuit board of claim 17, wherein the line width of each of the first and second circuit patterns is 10 μm or less, and
the line width of the third circuit pattern exceeds 10 μm.

19. The printed circuit board of claim 17, wherein the first circuit pattern, the second circuit pattern, and the third circuit pattern are arranged as a plurality of first circuit patterns, a plurality of second circuit patterns, and a plurality of third circuit patterns, respectively,
wherein an interval between the plurality of third circuit patterns is wider than an interval between circuit patterns among the plurality of first circuit patterns and the plurality of second circuit patterns.

20. The printed circuit board of claim 19, wherein one first circuit pattern among the plurality of first circuit patterns and one second circuit pattern among the plurality of second circuit patterns are alternately and repeatedly arranged.

21. The printed circuit board of claim 19, wherein a pair of first circuit patterns among the plurality of first circuit patterns and one second circuit pattern among the plurality of second circuit patterns are alternately and repeatedly arranged.

22. The printed circuit board of claim 17, further comprising a connection via passing through the first insulating layer and connecting at least a portion of the first wiring layer and at least a portion of the second wiring layer to each other,
wherein the connection via is tapered to substantially decrease a width in a direction from a surface contacting the second wiring layer to a surface contacting the first wiring layer.

23. The printed circuit board of claim 17, wherein the first and second circuit patterns do not comprise a seed metal layer, and
the third circuit pattern comprises the seed metal layer.

24. A method for manufacturing a printed circuit board, comprising:
forming a plurality of first metal patterns on a substrate;
forming a metal layer covering the plurality of first metal patterns on the substrate, and including a metal, different from that of the plurality of first metal patterns;
forming a plurality of second metal patterns on the metal layer, filling at least a portion of a space between external side surfaces of the metal layer, and including a metal, different from the metal of the metal layer, respectively;
etching a portion of the metal layer to expose at least a portion of each of the plurality of first metal patterns from the metal layer;
forming a first insulating layer on the plurality of first metal patterns and the plurality of second metal patterns;
removing the substrate; and
etching a remaining portion of the metal layer.

25. The method of claim 24, wherein the plurality of first metal patterns and the plurality of second metal patterns comprise copper (Cu), and
the metal layer comprises nickel (Ni).

26. The method of claim 24, wherein, in the forming a plurality of first metal patterns,
if a width of each of the plurality of first metal patterns is n, an interval between the plurality of first metal patterns substantially satisfies 3n, respectively, and in the forming a metal layer,
a thickness or a width of the metal layer substantially satisfies n.

27. The method of claim 24, further comprising, after the removing the substrate:
etching each of the plurality of first metal patterns to divide each of the plurality of first metal patterns into at least two first metal patterns.

28. The method of claim 27, wherein, in the forming a plurality of first metal patterns,
if a width of each of the plurality of first metal patterns is 3n, an interval between the plurality of first metal patterns substantially satisfies 3n, respectively, in the forming a metal layer,
a thickness or a width of the metal layer substantially satisfies n, and
in the dividing each of the plurality of first metal patterns into at least two first metal patterns,
a width of each of the at least two first metal patterns substantially satisfies n.

29. The method of claim 24, wherein, in the forming a plurality of first metal patterns, at least a portion of an edge of a top surface of each of the plurality of first metal patterns is formed to be rounded.

30. The method of claim 24, wherein, in the etching a portion of the metal layer,
the metal layer is etched such that a top surface has a step difference with a top surface of each of the plurality of first circuit patterns and a top surface of each of the plurality of second circuit patterns, respectively.

31. The method of claim 24, wherein the substrate comprises a detachable core, and a detachable metal layer disposed on the detachable core and including a metal, different from that of the metal layer, wherein, in the removing the substrate,
the detachable core is separated and removed from the detachable metal layer, and
the detachable metal layer is etched and removed.

32. The method of claim 24, further comprising, after the removing the substrate:
forming a dry film exposing a portion of at least one of the plurality of first metal patterns or the plurality of second metal patterns, on the plurality of first metal patterns and the plurality of second metal patterns; and
etching an exposed portion of at least one of the plurality of first metal patterns or the plurality of second metal patterns.

33. The method of claim 24, wherein, in the forming a plurality of first metal patterns,
at least one third metal pattern is further formed on the substrate,
in the forming a metal layer,
the metal layer further covers the at least one third metal pattern, and
in the forming a plurality of second metal patterns,
at least one fourth metal pattern is further formed on the metal layer, to fill at least a portion of a different space between external side surfaces of the metal layer, respectively, and
the metal layer includes metal, different from the at least one third metal pattern and the at least one fourth metal pattern.

34. The method of claim 33, further comprising, after the forming a first insulating layer:
forming a second wiring layer on the first insulating layer;
forming a first connection via passing through the first insulating layer and connected to at least a portion of the second wiring layer;
forming a second insulating layer covering at least a portion of the second wiring layer on the first insulating layer;
forming a third wiring layer on the second insulating layer; and
forming a second connection via passing through the second insulating layer and connected to at least a portion of the third wiring layer.

35. The method of claim 34, further comprising, after the etching a remaining portion of the metal layer:
forming a first resist layer covering at least a portion of the plurality of first metal patterns, at least a portion of the plurality of second metal patterns, at least a portion of the at least one third metal pattern, and at least a portion of the at least one fourth metal pattern, on the first insulating layer; and
forming a second resist layer covering at least a portion of the third wiring layer on the second insulating layer.

36. A printed circuit board comprising:
an insulating layer;
a first wiring layer protruding from an upper surface of the insulating layer, and including circuit patterns having different thicknesses;
a second wiring layer disposed below the insulating layer; and
a connection via passing through the insulating layer and connecting the first wiring layer and the second wiring layer to each other,
wherein the connection via is tapered to substantially decrease a width in a direction from a surface contacting the second wiring layer to a surface contacting the first wiring layer.

37. The printed circuit board of claim 36, wherein the first wiring layer includes first circuit patterns having a substantially same thickness and second circuit patterns having a substantially same thickness, and
the thickness of the second circuit patterns is less than the thickness of the first circuit patterns.

38. The printed circuit board of claim 37, wherein the first circuit patterns and the second circuit patterns are alternately disposed.

39. The printed circuit board of claim 37, wherein the second circuit patterns and pairs of the first circuit patterns are alternately disposed.

40. The printed circuit board of claim 37, wherein an interval between one pair of the first circuit patterns, disposed between one pair of the second circuit patterns, decreases toward the insulating layer.

41. The printed circuit board of claim 37, wherein a portion of the insulating layer between one of the second circuit patterns and one of the first circuit patterns has a step difference with a portion of the insulating layers between the one of the first circuit patterns and another of the first circuit patterns.

42. The printed circuit board of claim 37, wherein the first wiring layer includes a third circuit pattern having a thickness greater than the thickness of the second circuit patterns and having a width greater than a width of the second circuit patterns and a width of the first circuit patterns, and
the connection via extends from the third circuit pattern.

43. The printed circuit board of claim 42, wherein the thickness of the third circuit pattern is substantially the same as the thickness of the first circuit patterns.

44. The printed circuit board of claim 36, wherein the circuit patterns of the first wiring layer are partially embedded in the insulating layer.

45. The printed circuit board of claim 36, wherein the circuit patterns include one type of circuit patterns each having one or more protrusions on a side in contact with the insulating layer, and another type of circuit patterns each having one or more grooves on a side in contact with the insulating layer.

46. The printed circuit board of claim 45, wherein the circuit patterns having the protrusions and the circuit patterns having the grooves are periodically disposed.

47. A printed circuit board comprising:
an insulating layer; and
a wiring layer protruding from an upper surface of the insulating layer, and including first circuit patterns and second circuit patterns periodically disposed,
wherein each of the first circuit patterns has one or more grooves on a side in contact with the insulating layer, and each of the second circuit patterns has one or more protrusions on a side in contact with the insulating layer.

48. The printed circuit board of claim 47, wherein the first circuit patterns and the second circuit patterns are alternately disposed.

49. The printed circuit board of claim 47, wherein the second circuit patterns and pairs of the first circuit patterns are alternately disposed.

50. The printed circuit board of claim 49, wherein an interval between one pair of the first circuit patterns, disposed between one pair of the second circuit patterns, decreases toward the insulating layer.

51. The printed circuit board of claim 47, wherein the first and second circuit patterns are partially embedded in the insulating layer.

52. The printed circuit board of claim 47, wherein a portion of the insulating layer between one of the second circuit patterns and one of the first circuit patterns has a step difference with a portion of the insulating layers between the one of the first circuit patterns and another of the first circuit patterns.
